(19) United States
(12) Patent Application Publication
(10) Pub. No.: US 2024/0370756 A1
(43) Pub. Date: Nov. 7, 2024

(54) Connecting Circuitry in a Cap Wafer of a Superconducting Quantum Processing Unit (QPU)

(71) Applicant: Rigetti & Co, LLC, Berkeley, CA (US)

(72) Inventors: Feyza Oruc, Fremont, CA (US); Shane Arthur Caldwell, Oakland, CA (US); Andrew Joseph Bestwick, Berkeley, CA (US); Riccardo Manenti, Berkeley, CA (US); Dennis Chen Feng, Sunnyvale, CA (US); Keith Matthew Jackson, Berkeley, CA (US); Mark Field, Campbell, CA (US)

(73) Assignee: Rigetti & Co, LLC, Berkeley, CA (US)

(21) Appl. No.: 18/452,097

(22) Filed: Aug. 18, 2023

Related U.S. Application Data
(63) Continuation of application No. PCT/US22/16918, filed on Feb. 18, 2022.
(60) Provisional application No. 63/151,347, filed on Feb. 19, 2021.

(51) Int. Cl. G06N 10/40; H10N 69/00

(52) U.S. Cl. CPC G06N 10/40; H10N 69/00

(57) ABSTRACT

In a general aspect, a superconducting quantum processing unit (QPU) includes a cap wafer that has multiple connected circuitry portions. In some cases, a QPU includes first and second substrates. The first substrate includes a first surface, a recess, and first superconducting circuitry. The recess is defined by sidewalls and a recessed surface. The recessed surface resides at a depth in the first substrate. The first superconducting circuitry includes a first circuitry portion on the first surface of the first substrate; a second circuitry portion on the recessed surface of the first substrate; and a connection disposed on at least one of the sidewalls and connecting the first and second circuitry portions. The second substrate includes second superconducting circuitry, which includes a quantum circuit device. The first and second substrates are arranged such that the recess forms an enclosure that houses the quantum circuit device.

### CROSS-REFERENCE TO RELATED APPLICATIONS

This application claims priority to U.S. Provisional Application No. 63/151,347 filed on Feb. 19, 2021, and entitled “Connecting Circuitry in a Cap Wafer of a Superconducting Quantum Processing Unit (QPU).” The above-referenced priority application is hereby incorporated by reference.

### BACKGROUND

The following description relates to connecting circuitry in a cap wafer of a superconducting quantum processing unit (QPU) that includes multiple qubit devices for quantum information processing.

Quantum computers can perform computational tasks by storing and processing information within quantum states of quantum systems. For example, qubits (i.e., quantum bits) can be stored in and represented by an effective two-level sub-manifold of a quantum coherent physical system. A variety of physical systems have been proposed for quantum computing applications. Examples include superconducting circuits, trapped ions, spin systems and others.

### BRIEF DESCRIPTION OF THE DRAWINGS

FIG. 1 is a block diagram of an example computing environment.

FIG. 2 is a schematic diagram of a cross-sectional view of an example quantum processing unit.

FIG. 3A is a schematic diagram of an exploded view of an example quantum processing unit.

FIG. 3B is a schematic diagram of a perspective view of an example quantum processing unit.

FIGS. 4A-4B are schematic diagrams of a top view and a cross-sectional view of an example quantum processing unit.

FIG. 5 is a schematic diagram of a top view of an example cap wafer.

FIG. 6A is a schematic diagram of a cross-sectional view of an example quantum processing unit.

FIG. 6B is a schematic diagram of a cross-sectional view of an example quantum processing unit.

FIG. 6C is a schematic diagram of an exploded view of an example quantum processing unit.

FIG. 7A are schematic diagrams of a perspective view and a cross-sectional view of an example cap wafer.

FIG. 7B are schematic diagrams of a perspective view and a cross-sectional view of an example device wafer.

FIG. 7C are schematic diagrams of a perspective view and cross-sectional views of an example quantum processing unit.

FIG. 8 is a flow chart showing aspects of an example fabrication process.

### DETAILED DESCRIPTION

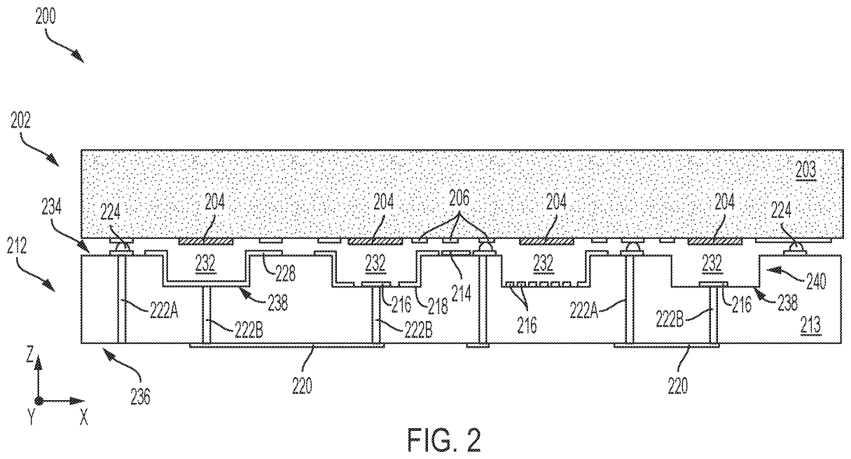

In some aspects of what is described here, a quantum processing unit includes a device wafer with quantum circuit devices based on, for example, superconducting devices, electron spin, nuclear spin, neutral atom, polarized photons, quantum dots, or trapped ions, and other superconducting circuitry. The quantum processing unit further includes a cap wafer bonded with the device wafer. A cap wafer includes recesses, each of which is defined by a recessed surface and sidewalls. Recesses on the cap wafer form respective enclosures that house the respective quantum circuit devices on the device wafer. The cap wafer may include various superconducting circuitry (e.g., the circuitry 214, 216, 218, 220 of FIG. 2) on various surfaces (e.g., the first surface 234, the second surface 236, the recessed surface 238, and the sidewalls 240 of FIG. 2) of the cap wafer, for example, to providing various types of functionality, which can improve performance of a quantum processing unit or provide other advantages. Further, the cap wafer may include other features, such as, for example, electrically conductive vias (e.g., the conductive vias 222A, 222B of FIG. 2) that can be used to galvanically couple circuitry on various surfaces.

In some implementations, recesses in the cap wafer can provide technical advantages and improvements relative to existing quantum information processing technologies. In some instances, a participation ratio of electric fields around a quantum circuit device can be tuned to improve QPU performance attributes, such as coherence times, flux cross-talk, gate fidelity, or another performance parameter. For example, a participation ratio can be tuned by controlling a depth of a recess and thus the distance between a ground plane disposed on a recessed surface of the recess and a respective quantum circuit device enclosed by the recess.

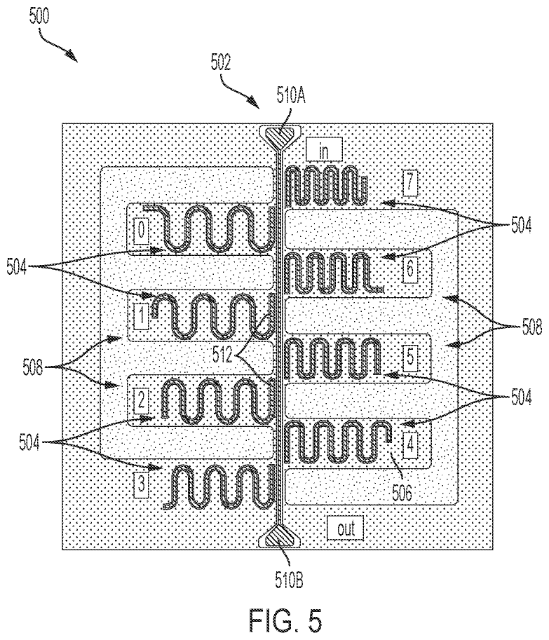

In some implementations, various circuitry on a cap wafer may include a variety of circuit elements to control or readout quantum circuit devices on a device wafer. For example, circuitry on a cap wafer may include flux bias lines that can be inductively coupled to quantum circuit devices on a device wafer to provide magnetic flux locally, for example, to tune their frequencies. Circuitry on a cap wafer may also include microwave lines which can be capacitively coupled to quantum circuit devices, for example, to control qubits. In some examples, circuitry on a cap wafer includes microwave resonator devices which can be capacitively coupled to quantum circuit devices, for example, to the readout resonator devices 500 shown in FIG. 5. In certain instances, other circuit elements, such as filters, isolators, circulators, or amplifiers, which would otherwise be deployed in an external module or package, can be integrated on the cap wafer.

In some implementations, circuitry on the cap wafer can provide technical advantages and improvements relative to existing quantum information processing technologies. In some instances, control signals can be supplied to quantum circuit devices on a device wafer (e.g., galvanically, capacitively, or inductively) through circuitry, electrically conductive vias, and/or bonding bumps on a cap wafer. Therefore, the methods and techniques presented here can free up space on a device wafer allowing for more dense quantum circuits and reduce the number of interconnections. In some instances, a cap wafer can provide opportunities to simplify the circuit design and improve the yield of a quantum integrated circuit (QuIC) on a device wafer.

In some instances, ground planes can be included on a cap wafer, which may allow better isolations of quantum circuit devices on a device wafer. Ground planes on a cap wafer can be used to guide, disperse, and remove supercurrents away from quantum circuit devices. Consequently, unpredictable non-localized interactions, flux crosstalk, and coherent error caused by the propagation of the supercurrents can be reduced.

In some implementations, the systems and techniques described here can provide improved protection for quantum circuit devices on a device wafer. For example, a conductive layer can be formed on a recessed surface and sidewalls of a recess on a cap wafer, which, when being arranged around a quantum circuit device of a device wafer, can effectively form a Faraday cage that reduces electrical noise. For another example, a superconducting layer can be formed on a recessed surface and sidewalls of a recess, which, when being arranged around a quantum circuit device, can be used as a magnetic shield to reduce the impact of stray magnetic fields on the quantum circuit device. In some instances, a cap wafer could provide protection to quantum circuit devices from other sources of interference and noise, including electromagnetic pulse damage, electrostatic discharge, ionizing radiation, and/or thermal radiation. For example, a cap wafer could also improve the performance of Radio Frequency Monolithic Microwave Integrated Circuit (RF MMIC) chips by reducing interference, either from the MMIC itself or from neighboring RF circuitry. For instance, a cap wafer can include a barrier layer for reflecting thermal radiation to reduce heat load on quantum circuit devices. In addition, a cap wafer may include thermal pathways to improve heatsinking. In some instances, an antenna or an array of antennas may be included on a cap wafer for the RF-MMIC chips on a device wafer, where dimensions of the antenna and the RF-MMIC chip become comparable.

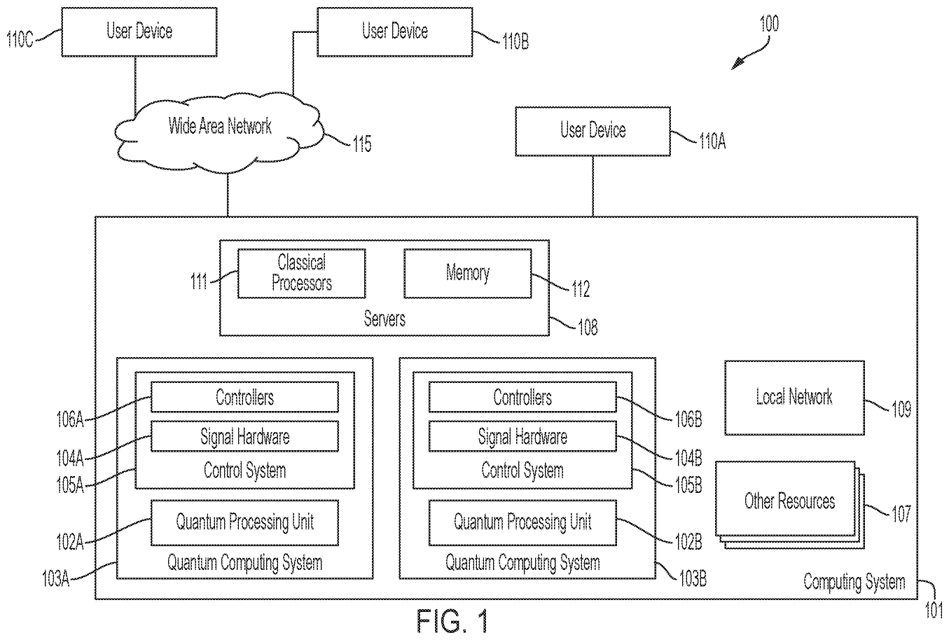

FIG. 1 is a block diagram of an example computing environment 100. The example computing environment 100 shown in FIG. 1 includes a computing system 101 and user devices 110A, 110B, 110C. A computing environment may include additional or different features, and the components of a computing environment may operate as described with respect to FIG. 1 or in another manner.

The example computing system 101 includes classical and quantum computing resources and exposes their functionality to the user devices 110A, 110B, 110C (referred to collectively as “user devices 110”). The computing system 101 shown in FIG. 1 includes one or more servers 108, quantum computing systems 103A, 103B, a local network 109 and other resources 107. The computing system 101 may also include one or more user devices (e.g., the user device 110A) as well as other features and components. A computing system may include additional or different features, and the components of a computing system may operate as described with respect to FIG. 1 or in another manner.

The example computing system 101 can provide services to the user devices 110, for example, as a cloud-based or remote-accessed computer system, as a distributed computing resource, as a supercomputer or another type of high-performance computing resource, or in another manner. The computing system 101 or the user devices 110 may also have access to one or more other quantum computing systems (e.g., quantum computing resources that are accessible through the wide area network 115, the local network 109 or otherwise).

The user devices 110 shown in FIG. 1 may include one or more classical processors, memory, user interfaces, communication interfaces, and other components. For instance, the user devices 110 may be implemented as laptop computers, desktop computers, smartphones, tablets or other types of computer devices. In the example shown in FIG. 1, to access computing resources of the computing system 101, the user devices 110 send information (e.g., programs, instructions, commands, requests, input data, etc.) to the servers 108; and in response, the user devices 110 receive information (e.g., application data, output data, prompts, alerts, notifications, results, etc.) from the servers 108. The user devices 110 may access services of the computing system 101 in another manner, and the computing system 101 may expose computing resources in another manner.

In the example shown in FIG. 1, the local user device 110A operates in a local environment with the servers 108 and other elements of the computing system 101. For instance, the user device 110A may be co-located with (e.g., located within 0.5 to 1 km of) the servers 108 and possibly other elements of the computing system 101. As shown in FIG. 1, the user device 110A communicates with the servers 108 through a local data connection.

The local data connection in FIG. 1 is provided by the local network 109. For example, some or all of the servers 108, the user device 110A, the quantum computing systems 103A, 103B and the other resources 107 may communicate with each other through the local network 109. In some implementations, the local network 109 operates as a communication channel that provides one or more low-latency communication pathways from the server 108 to the quantum computer systems 103A, 103B (or to one or more of the elements of the quantum computer systems 103A, 103B). The local network 109 can be implemented, for instance, as a wired or wireless Local Area Network, an Ethernet connection, or another type of wired or wireless connection. The local network 109 may include one or more wired or wireless routers, wireless access points (WAPs), wireless mesh nodes, switches, high-speed cables, or a combination of these and other types of local network hardware elements. In some cases, the local network 109 includes a software-defined network that provides communication among virtual resources, for example, among an array of virtual machines operating on the server 108 and possibly elsewhere.

In the example shown in FIG. 1, the remote user devices 110B, 110C operate remote from the servers 108 and other elements of the computing system 101. For instance, the user devices 110B, 110C may be located at a remote distance (e.g., more than 1 km, 10 km, 100 km, 1,000 km, 10,000 km, or farther) from the servers 108 and possibly other elements of the computing system 101. As shown in FIG. 1, each of the user devices 110B, 110C communicates with the servers 108 through a remote data connection.

The remote data connection in FIG. 1 is provided by a wide area network 115, which may include, for example, the Internet or another type of wide area communication network. In some cases, remote user devices use another type of remote data connection (e.g., satellite-based connections, a cellular network, a virtual private network, etc.) to access the servers 108. The wide area network 115 may include one or more internet servers, firewalls, service hubs, base stations, or a combination of these and other types of remote networking elements. Generally, the computing environment 100 can be accessible to any number of remote user devices.

The example servers 108 shown in FIG. 1 can manage interaction with the user devices 110 and utilization of the quantum and classical computing resources in the computing system 101. For example, based on information from the user devices 110, the servers 108 may delegate computational tasks to the quantum computing systems 103A, 103B and the other resources 107; the servers 108 can then send information to the user devices 110 based on output data from the computational tasks performed by the quantum computing systems 103A, 103B and the other resources 107.

As shown in FIG. 1, the servers 108 are classical computing resources that include classical processors 111 and memory 112. The servers 108 may also include one or more communication interfaces that allow the servers to communicate via the local network 109, the wide area network 115 and possibly other channels. In some implementations, the servers 108 may include a host server, an application server, a virtual server or a combination of these and other types of servers. The servers 108 may include additional or different features, and may operate as described with respect to FIG. 1 or in another manner.

The classical processors 111 can include various kinds of apparatus, devices, and machines for processing data, including, by way of example, a microprocessor, a central processing unit (CPU), a graphics processing unit (GPU), an FPGA (field programmable gate array), an ASIC (application specific integrated circuit), or combinations of these. The memory 112 can include, for example, a random access memory (RAM), a storage device (e.g., a writable read-only memory (ROM) or others), a hard disk, or another type of storage medium. The memory 112 can include various forms of volatile or non-volatile memory, media and memory devices, etc.

Each of the example quantum computing systems 103A, 103B operates as a quantum computing resource in the computing system 101. The other resources 107 may include additional quantum computing resources (e.g., quantum computing systems, quantum virtual machines (QVMs) or quantum simulators) as well as classical (non-quantum) computing resources such as, for example, digital microprocessors, specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), etc., or combinations of these and other types of computing modules.

In some implementations, the servers 108 generate programs, identify appropriate computing resources (e.g., a QPU or QVM) in the computing system 101 to execute the programs, and send the programs to the identified resources for execution. For example, the servers 108 may send programs to the quantum computing system 103A, the quantum computing system 103B or any of the other resources 107. The programs may include classical programs, quantum programs, hybrid classical/quantum programs, and may include any type of function, code, data, instruction set, etc.

In some instances, programs can be formatted as source code that can be rendered in human-readable form (e.g., as text) and can be compiled, for example, by a compiler running on the servers 108, on the quantum computing systems 103, or elsewhere. In some instances, programs can be formatted as compiled code, such as, for example, binary code (e.g., machine-level instructions) that can be executed directly by a computing resource. Each program may include instructions corresponding to computational tasks that, when performed by an appropriate computing resource, generate output data based on input data. For example, a program can include instructions formatted for a quantum computer system, a quantum virtual machine, a digital microprocessor, co-processor or other classical data processing apparatus, or another type of computing resource.

In some cases, a program may be expressed in a hardware-independent format. For example, quantum machine instructions may be provided in a quantum instruction language such as Quil, described in the publication “A Practical Quantum Instruction Set Architecture,” arXiv:1608.03355v2, dated Feb. 17, 2017, or another quantum instruction language. For instance, the quantum machine instructions may be written in a format that can be executed by a broad range of quantum processing units or quantum virtual machines. In some cases, a program may be expressed in high-level terms of quantum logic gates or quantum algorithms, in lower-level terms of fundamental qubit rotations and controlled rotations, or in another form. In some cases, a program may be expressed in terms of control signals (e.g., pulse sequences, delays, etc.) and parameters for the control signals (e.g., frequencies, phases, durations, channels, etc.). In some cases, a program may be expressed in another form or format.

In some implementations, the servers 108 include one or more compilers that convert programs between formats. For example, the servers 108 may include a compiler that converts hardware-independent instructions to binary programs for execution by the quantum computing systems 103A, 103B. In some cases, a compiler can compile a program to a format that targets a specific quantum resource in the computer system 101. For example, a compiler may generate a different binary program (e.g., from the same source code) depending on whether the program is to be executed by the quantum computing system 103A or the quantum computing system 103B.

In some cases, a compiler generates a partial binary program that can be updated, for example, based on specific parameters. For instance, if a quantum program is to be executed iteratively on a quantum computing system with varying parameters on each iteration, the compiler may generate the binary program in a format that can be updated with specific parameter values at runtime (e.g., based on feedback from a prior iteration, or otherwise). In some cases, a compiler generates a full binary program that does not need to be updated or otherwise modified for execution.

In some implementations, the servers 108 generate a schedule for executing programs, allocate computing resources in the computing system 101 according to the schedule, and delegate the programs to the allocated computing resources. The servers 108 can receive, from each computing resource, output data from the execution of each program. Based on the output data, the servers 108 may generate additional programs that are then added to the schedule, output data that is provided back to a user device 110, or perform another type of action.

In some implementations, all or part of the computing environment operates as a cloud-based quantum computing (QC) environment, and the servers 108 operate as a host system for the cloud-based QC environment. The cloud-based QC environment may include software elements that operate on both the user devices 110 and the computer system 101 and interact with each other over the wide area network 115. For example, the cloud-based QC environment may provide a remote user interface, for example, through a browser or another type of application on the user devices 110. The remote user interface may include, for example, a graphical user interface or another type of user interface that obtains input provided by a user of the cloud-based QC environment. In some cases the remote user interface includes, or has access to, one or more application programming interfaces (APIs), command line interfaces, graphical user interfaces, or other elements that expose the services of the computer system 101 to the user devices 110.

In some cases, the cloud-based QC environment may be deployed in a “serverless” computing architecture. For instance, the cloud-based QC environment may provide on-demand access to a shared pool of configurable computing resources (e.g., networks, servers, storage, applications, services, quantum computing resources, classical computing resources, etc.) that can be provisioned for requests from user devices 110. Moreover, the cloud-based computing systems 104 may include or utilize other types of computing resources, such as, for example, edge computing, fog computing, etc.

In an example implementation of a cloud-based QC environment, the servers 108 may operate as a cloud provider that dynamically manages the allocation and provisioning of physical computing resources (e.g., GPUs, CPUs, QPUs, etc.). Accordingly, the servers 108 may provide services by defining virtualized resources for each user account. For instance, the virtualized resources may be formatted as virtual machine images, virtual machines, containers, or virtualized resources that can be provisioned for a user account and configured by a user. In some cases, the cloud-based QC environment is implemented using a resource such as, for example, OPENSTACK®. OPENSTACK® is an example of a software platform for cloud-based computing, which can be used to provide virtual servers and other virtual computing resources for users.

In some cases, the server 108 stores quantum machine images (QMI) for each user account. A quantum machine image may operate as a virtual computing resource for users of the cloud-based QC environment. For example, a QMI can provide a virtualized development and execution environment to develop and run programs (e.g., quantum programs or hybrid classical/quantum programs). When a QMI operates on the server 108, the QMI may engage either of the quantum processor units 102A, 102B, and interact with a remote user device (110B or 110C) to provide a user programming environment. The QMI may operate in close physical proximity to and have a low-latency communication link with the quantum computing systems 103A, 103B. In some implementations, remote user devices connect with QMIs operating on the servers 108 through secure shell (SSH) or other protocols over the wide area network 115.

In some implementations, all or part of the computing system 101 operates as a hybrid computing environment. For example, quantum programs can be formatted as hybrid classical/quantum programs that include instructions for execution by one or more quantum computing resources and instructions for execution by one or more classical resources. The servers 108 can allocate quantum and classical computing resources in the hybrid computing environment, and delegate programs to the allocated computing resources for execution. The quantum computing resources in the hybrid environment may include, for example, one or more quantum processing units (QPUs), one or more quantum virtual machines (QVMs), one or more quantum simulators, or possibly other types of quantum resources. The classical computing resources in the hybrid environment may include, for example, one or more digital microprocessors, one or more specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), or other types of computing modules.

In some cases, the servers 108 can select the type of computing resource (e.g., quantum or classical) to execute an individual program, or part of a program, in the computing system 101. For example, the servers 108 may select a particular quantum processing unit (QPU) or other computing resource based on availability of the resource, speed of the resource, information or state capacity of the resource, a performance metric (e.g., process fidelity) of the resource, or based on a combination of these and other factors. In some cases, the servers 108 can perform load balancing, resource testing and calibration, and other types of operations to improve or optimize computing performance.

Each of the example quantum computing systems 103A, 103B shown in FIG. 1 can perform quantum computational tasks by executing quantum machine instructions (e.g., a binary program compiled for the quantum computing system). In some implementations, a quantum computing system can perform quantum computation by storing and manipulating information within quantum states of a composite quantum system. For example, qubits (i.e., quantum bits) can be stored in and represented by an effective two-level sub-manifold of a quantum coherent physical system. In some instances, quantum logic can be executed in a manner that allows large-scale entanglement within the quantum system. Control signals can manipulate the quantum states of individual qubits and the joint states of multiple qubits. In some instances, information can be read out from the composite quantum system by measuring the quantum states of the qubits. In some implementations, the quantum states of the qubits are read out by measuring the transmitted or reflected signal from auxiliary quantum devices that are coupled to individual qubits.

In some implementations, a quantum computing system can operate using gate-based models for quantum computing. For example, the qubits can be initialized in an initial state, and a quantum logic circuit comprised of a series of quantum logic gates can be applied to transform the qubits and extract measurements representing the output of the quantum computation. Individual qubits may be controlled by single-qubit quantum logic gates, and pairs of qubits may be controlled by two-qubit quantum logic gates (e.g., entangling gates that are capable of generating entanglement between the pair of qubits). In some implementations, a quantum computing system can operate using adiabatic or annealing models for quantum computing. For instance, the qubits can be initialized in an initial state, and the controlling Hamiltonian can be transformed adiabatically by adjusting control parameters to another state that can be measured to obtain an output of the quantum computation.

In some models, fault-tolerance can be achieved by applying a set of high-fidelity control and measurement operations to the qubits. For example, quantum error correcting schemes can be deployed to achieve fault-tolerant quantum computation. Other computational regimes may be used; for example, quantum computing systems may operate in non-fault-tolerant regimes. In some implementations, a quantum computing system is constructed and operated according to a scalable quantum computing architecture. For example, in some cases, the architecture can be scaled to a large number of qubits to achieve large-scale general purpose coherent quantum computing. Other architectures may be used; for example, quantum computing systems may operate in small-scale or non-scalable architectures.

The example quantum computing system 103A shown in FIG. 1 includes a quantum processing unit 102A and a control system 105A, which controls the operation of the quantum processing unit 102A. Similarly, the example quantum computing system 103B includes a quantum processing unit 102B and a control system 105B, which controls the operation of a quantum processing unit 102B. A quantum computing system may include additional or different features, and the components of a quantum computing system may operate as described with respect to FIG. 1 or in another manner.

In some instances, all or part of the quantum processing unit 102A functions as a quantum processor, a quantum memory, or another type of subsystem. In some examples, the quantum processing unit 102A includes a quantum circuit system. The quantum circuit system may include qubit devices, readout devices and possibly other devices that are used to store and process quantum information. In some cases, the quantum processing unit 102A includes a superconducting circuit, and the qubit devices are implemented as circuit devices that include Josephson junctions, for example, in superconducting quantum interference device (SQUID) loops or other arrangements, and are controlled by radio-frequency signals, microwave signals, and bias signals delivered to the quantum processing unit 102A. In some cases, the quantum processing unit 102A includes an ion trap system, and the qubit devices are implemented as trapped ions controlled by optical signals delivered to the quantum processing unit 102A. In some cases, the quantum processing unit 102A includes a spin system, and the qubit devices are implemented as nuclear or electron spins controlled by microwave or radio-frequency signals delivered to the quantum processing unit 102A. The quantum processing unit 102A may be implemented based on another physical modality of quantum computing.

The quantum processing unit 102A may include, or may be deployed within, a controlled environment. The controlled environment can be provided, for example, by shielding equipment, cryogenic equipment, and other types of environmental control systems. In some examples, the components in the quantum processing unit 102A operate in a cryogenic temperature regime and are subject to very low electromagnetic and thermal noise. For example, magnetic shielding can be used to shield the system components from stray magnetic fields, optical shielding can be used to shield the system components from optical noise, thermal shielding and cryogenic equipment can be used to maintain the system components at controlled temperature, etc.

In some implementations, the example quantum processing unit 102A can process quantum information by applying control signals to the qubits in the quantum processing unit 102A. The control signals can be configured to encode information in the qubits, to process the information by performing quantum logic gates or other types of operations, or to extract information from the qubits. In some examples, the operations can be expressed as single-qubit quantum logic gates, two-qubit quantum logic gates, or other types of quantum logic gates that operate on one or more qubits. A quantum logic circuit, which includes a sequence of quantum logic operations, can be applied to the qubits to perform a quantum algorithm. The quantum algorithm may correspond to a computational task, a hardware test, a quantum error correction procedure, a quantum state distillation procedure, or a combination of these and other types of operations.

The quantum processing unit 102A may include a device wafer and a cap wafer that are bonded together, for example, using bonding bumps or in another manner. In some instances, the device wafer contains a superconducting circuit with one or more quantum circuit devices. In some instances, the cap wafer contains one or more recesses, each defined by a recessed surface and sidewalls. The cap wafer may also contain various superconducting circuitry disposed at various locations, for example, on the recessed surface of the recess, the sidewalls, the front and back surfaces. The various superconducting circuitry of the cap wafer can provide various functionality. For example, a cap wafer may include circuitry for inductively, capacitively, or galvanically coupling two or more quantum circuit devices on one or more device wafers. Circuitry may include a variety of circuit elements to control or readout quantum circuit devices (e.g., qubit devices). For instance, circuitry on a cap wafer may include coupling lines, microwave lines, microwave feedlines, flux bias lines, combined flux bias and microwave lines, tunable coupler devices, resonator devices, filters, isolators, circulators, amplifiers, or other circuit elements. In some instances, circuitry at different positions of a cap wafer may be connected through conductive pathways on one or more sidewalls of recesses or through conductive vias through the substrate of the cap wafer. In some implementations, the device wafer and the cap wafer may be implemented as any one of the example device wafers 202, 302A, 302B, 302C, 322A, 322B, 322C, 322D, 402, 602, 632, 672, or 730 and example cap wafers 212, 304, 324, 404, 500, 604, 634, 674, or 718 as shown in FIG. 2, 3A-3B, 4A-4B, 5, 6A-6C, or 7A-7C. In some instances, a cap wafer may be communicably coupled to the control system 105A, e.g., to receive control signals or transmit readout signals.

The example control system 105A includes controllers 106A and signal hardware 104A. Similarly, control system 105B includes controllers 106B and signal hardware 104B. All or part of the control systems 105A, 105B can operate in a room-temperature environment or another type of environment, which may be located near the respective quantum processing units 102A, 102B. In some cases, the control systems 105A, 105B include classical computers, signaling equipment (microwave, radio, optical, bias, etc.), electronic systems, vacuum control systems, refrigerant control systems or other types of control systems that support operation of the quantum processing units 102A, 102B.

The control systems 105A, 105B may be implemented as distinct systems that operate independent of each other. In some cases, the control systems 105A, 105B may include one or more shared elements; for example, the control systems 105A, 105B may operate as a single control system that operates both quantum processing units 102A, 102B. Moreover, a single quantum computer system may include multiple quantum processing units, which may operate in the same controlled (e.g., cryogenic) environment or in separate environments.

The example signal hardware 104A includes components that communicate with the quantum processing unit 102A. The signal hardware 104A may include, for example, waveform generators, amplifiers, digitizers, high-frequency sources, DC sources, AC sources, etc. The signal hardware may include additional or different features and components. In the example shown, components of the signal hardware 104A are adapted to interact with the quantum processing unit 102A. For example, the signal hardware 104A can be configured to operate in a particular frequency range, configured to generate and process signals in a particular format, or the hardware may be adapted in another manner.

In some instances, one or more components of the signal hardware 104A generate control signals, for example, based on control information from the controllers 106A. The control signals can be delivered to the quantum processing unit 102A during operation of the quantum computing system 103A. For instance, the signal hardware 104A may generate signals to implement quantum logic operations, readout operations or other types of operations. As an example, the signal hardware 104A may include arbitrary waveform generators (AWGs) that generate electromagnetic waveforms (e.g., microwave or radio-frequency) or laser systems that generate optical waveforms. The waveforms or other types of signals generated by the signal hardware 104A can be delivered to devices in the quantum processing unit 102A to operate qubit devices, readout devices, bias devices, coupler devices or other types of components in the quantum processing unit 102A.

In some instances, the signal hardware 104A receives and processes signals from the quantum processing unit 102A. The received signals can be generated by the execution of a quantum program on the quantum computing system 103A. For instance, the signal hardware 104A may receive signals from the devices in the quantum processing unit 102A in response to readout or other operations performed by the quantum processing unit 102A. Signals received from the quantum processing unit 102A can be mixed, digitized, filtered, or otherwise processed by the signal hardware 104A to extract information, and the information extracted can be provided to the controllers 106A or handled in another manner. In some examples, the signal hardware 104A may include a digitizer that digitizes electromagnetic waveforms (e.g., microwave or radio-frequency) or optical signals, and a digitized waveform can be delivered to the controllers 106A or to other signal hardware components. In some instances, the controllers 106A process the information from the signal hardware 104A and provide feedback to the signal hardware 104A; based on the feedback, the signal hardware 104A can in turn generate new control signals that are delivered to the quantum processing unit 102A.

In some implementations, the signal hardware 104A includes signal delivery hardware that interfaces with the quantum processing unit 102A. For example, the signal hardware 104A may include filters, attenuators, directional couplers, multiplexers, diplexers, bias components, signal channels, isolators, amplifiers, power dividers and other types of components. In some instances, the signal delivery hardware performs preprocessing, signal conditioning, or other operations to the control signals to be delivered to the quantum processing unit 102A. In some instances, signal delivery hardware performs preprocessing, signal conditioning or other operations on readout signals received from the quantum processing unit 102A.

The example controllers 106A communicate with the signal hardware 104A to control operation of the quantum computing system 103A. The controllers 106A may include classical computing hardware that directly interface with components of the signal hardware 104A. The example controllers 106A may include classical processors, memory, clocks, digital circuitry, analog circuitry, and other types of systems or subsystems. The classical processors may include one or more single- or multi-core microprocessors, digital electronic controllers, special purpose logic circuitry, e.g., an FPGA (field programmable gate array) or an ASIC (application specific integrated circuit), or other types of data processing apparatus. The memory may include any type of volatile or non-volatile memory or another type of computer storage medium. The controllers 106A may also include one or more communication interfaces that allow the controllers 106A to communicate via the local network 109 and possibly other channels. The controllers 106A may include additional or different features and components.

In some implementations, the controllers 106A include memory or other components that store quantum state information, for example, based on qubit readout operations performed by the quantum computing system 103A. For instance, the states of one or more qubits in the quantum processing unit 102A can be measured by qubit readout operations, and the measured state information can be stored in a cache or other type of memory system in or more of the controllers 106A. In some cases, the measured state information is subsequently used in the execution of a quantum program, a quantum error correction procedure, a quantum processing unit (QPU) calibration or testing procedure, or another type of quantum process.

In some implementations, the controllers 106A include memory or other components that store a quantum program containing quantum machine instructions for execution by the quantum computing system 103A. In some instances, the controllers 106A can interpret the quantum machine instructions and perform hardware-specific control operations according to the quantum machine instructions. For example, the controllers 106A may cause the signal hardware 104A to generate control signals that are delivered to the quantum processing unit 102A to execute the quantum machine instructions.

In some instances, the controllers 106A extract qubit state information from qubit readout signals, for example, to identify the quantum states of qubits in the quantum processing unit 102A or for other purposes. For example, the controllers may receive the qubit readout signals (e.g., in the form of analog waveforms) from the signal hardware 104A, digitize the qubit readout signals, and extract qubit state information from the digitized signals. In some cases, the controllers 106A compute measurement statistics based on qubit state information from multiple shots of a quantum program. For example, each shot may produce a bitstring representing qubit state measurements for a single execution of the quantum program, and a collection of bitsrings from multiple shots may be analyzed to compute quantum state probabilities.

In some implementations, the controllers 106A include one or more clocks that control the timing of operations. For example, operations performed by the controllers 106A may be scheduled for execution over a series of clock cycles, and clock signals from one or more clocks can be used to control the relative timing of each operation or groups of operations. In some implementations, the controllers 106A may include classical computer resources that perform some or all of the operations of the servers 108 described above. For example, the controllers 106A may operate a compiler to generate binary programs (e.g., full or partial binary programs) from source code; the controllers 106A may include an optimizer that performs classical computational tasks of a hybrid classical/quantum program; the controllers 106A may update binary programs (e.g., at runtime) to include new parameters based on an output of the optimizer, etc.

The other quantum computer system 103B and its components (e.g., the quantum processing unit 102B, the signal hardware 104B and controllers 106B) can be implemented as described above with respect to the quantum computer system 103A; in some cases, the quantum computer system 103B and its components may be implemented or may operate in another manner.

In some implementations, the quantum computer systems 103A, 103B are disparate systems that provide distinct modalities of quantum computation. For example, the computer system 101 may include both an adiabatic quantum computer system and a gate-based quantum computer system. As another example, the computer system 101 may include a superconducting circuit-based quantum computer system and an ion trap-based quantum computer system. In such cases, the computer system 101 may utilize each quantum computing system according to the type of quantum program that is being executed, according to availability or capacity, or based on other considerations.

FIG. 2 is a schematic diagram of a cross-sectional view of an example quantum processing unit 200. The example quantum processing unit 200 includes a device wafer 202 and a cap wafer 212, which are bonded together by bonding bumps 224. The device wafer 202 contains quantum circuit devices 204 as part of a superconducting circuit 206. The quantum circuit devices 204 can be, for example, qubit devices (e.g., transmon devices, fluxonium devices, or other types of superconducting qubit devices), coupler devices, readout devices or other types of devices that are used for quantum information processing in the quantum processing unit 200. The quantum circuit devices 204 may include one or more Josephson junctions, capacitors, inductors, and other types of circuit elements. The cap wafer 204 includes recesses 232 and various superconducting circuitry (e.g., 214, 216, 218, 220, and 222) disposed at various positions of the cap wafer 204 providing various functionalities. In some implementations, the use of the cap wafer 212 can improve coherence times of quantum circuit devices 204. In some implementations, the example quantum processing unit 200 may include additional and different features or components and components of the example quantum processing unit 200 may be implemented in another manner.

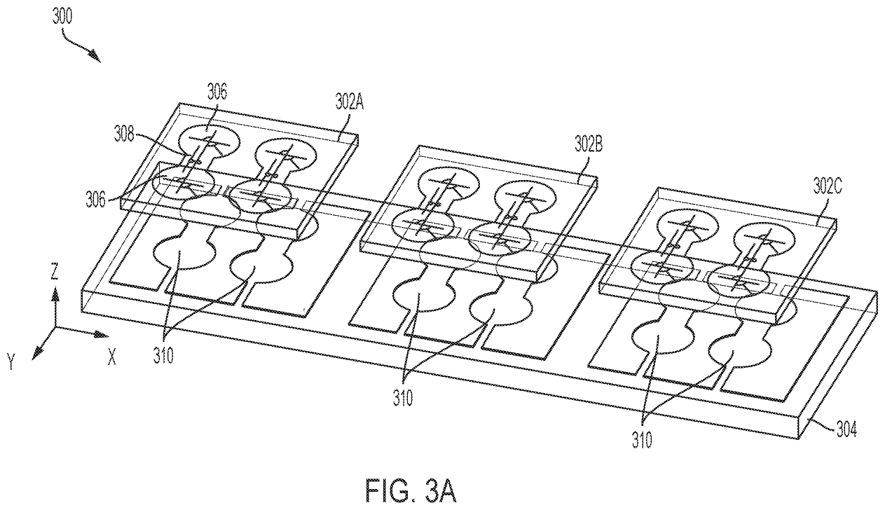

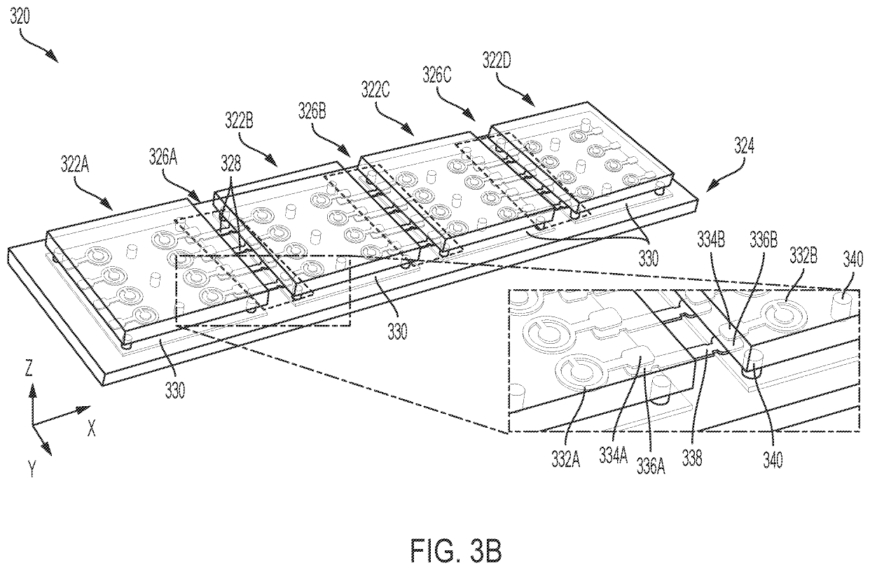

As shown in the example quantum processing unit 200, the device wafer 202 includes a first substrate 203. The first substrate 203 supporting the superconducting circuit 206 and the quantum circuit devices 204 is referred to as the device wafer 202. Similarly, the cap wafer 212 includes a second substrate 213. The second substrate 213 defining the recesses 232 and supporting the various superconducting circuitry (e.g., circuitry portions 214, 216, 218, 220, and 222) is referred to as the cap wafer 212. In some implementations, the quantum circuit devices 204 may include a two-dimensional array of qubit devices (e.g., on the surface along XY plane) and the recesses 232 of the cap wafer 212 may be arranged so as to form encapsulation for respective quantum circuit devices 204 when the cap wafer 212 and the device wafer 202 are bonded together. In some implementations, the example quantum processing unit 200 may include more than one device wafer 202 bonded to the same cap wafer 212 on the same side or on the opposite side. The cap wafer 212 can be used to inductively, capacitively or galvanically couple multiple quantum circuit devices 204 fabricated on multiple device wafers 202, or multiple dies (e.g., the device dies 302A, 302B, and 302C as shown in FIG. 3A).

In some implementations, the first and second substrates 203, 213 may include a dielectric substrate (e.g., silicon, sapphire, etc.). In certain examples, the first and second substrates 203, 213 may include an elemental semiconductor material such as, for example, silicon (Si), germanium (Ge), selenium (Se), tellurium (Te), or another elemental semiconductor. In some instances, the first and second substrates 203, 213 may also include a compound semiconductor such as silicon germanium (SiGe), silicon carbide (SiC), silicon germanium carbide (SiGeC), aluminum oxide (sapphire), gallium arsenide (GaAs), indium arsenide (InAs), indium phosphide (InP), gallium arsenic phosphide (GaAsP), or gallium indium phosphide (GaInP). In some instances, the first and second substrates 203, 213 may also include a superlattice with elemental or compound semiconductor layers. In some instances, the first and second substrates 203, 213 include an epitaxial layer. In some examples, the first and second substrates 203, 213 may have an epitaxial layer overlying a bulk semiconductor or may include a semiconductor-on-insulator (SOI) structure.

The quantum circuit devices 204 and the superconducting circuit 206 on the device wafer 202 and the various superconducting circuitry (e.g., the circuitry portions 214, 216, 218, 220, and 222) on the cap wafer 212 include superconducting materials. In some implementations, the superconducting materials may be superconducting metals, such as aluminum (Al), niobium (Nb), tantalum (Ta), vanadium (V), tungsten (W), indium (In), titanium (Ti), Lanthanum (La), lead (Pb), tin (Sn), and/or zirconium (Zr), that are superconducting at an operating temperature of the example quantum processing unit 200, or another superconducting metal. In some implementations, the superconducting materials may include superconducting metal alloys, such as molybdenum-rhenium (Mo/Re), niobium-tin (Nb/Sn), or another superconducting metal alloy. In some implementations, the superconducting materials may include superconducting compound materials, including superconducting metal nitrides and superconducting metal oxides, such as titanium-nitride (TiN), niobium-nitride (NbN), zirconium-nitride (ZrN), hafnium-nitride (HfN), vanadium-nitride (VN), tantalum-nitride (TaN), molybdenum-nitride (MoN), yttrium barium copper oxide (Y—Ba—Cu—O), or another superconducting compound material. In some instances, the superconducting materials may include multilayer superconductor-insulator heterostructures.

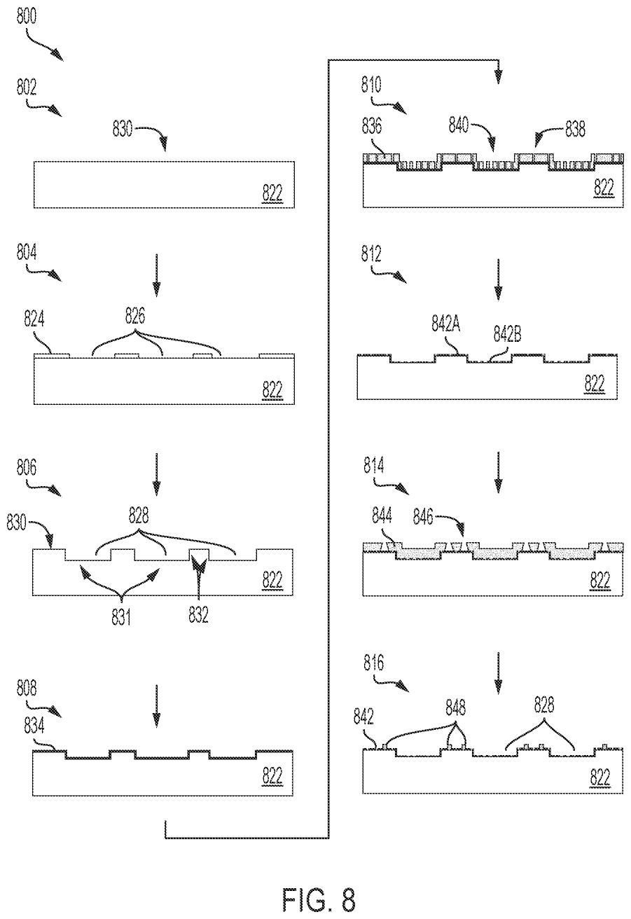

In some implementations, the quantum circuit devices 204 and the superconducting circuit 206 can be formed on a top surface of the first substrate and patterned using a microfabrication process or in another manner. For example, the superconducting circuit 206 and the quantum circuit devices 204 may be formed by performing at least some of the following fabrication steps: using chemical vapor deposition (CVD), physical vapor deposition (PVD), atomic layer deposition (ALD), and/or other suitable techniques to deposit respective superconducting layers on the first substrate; and performing one or more patterning processes (e.g., a lithography process, a dry/wet etching process, a soft/hard baking process, a cleaning process, etc.) to form openings in the respective superconducting layers. For example, a cap wafer may be formed with respect to the example process 800 shown in FIG. 8.

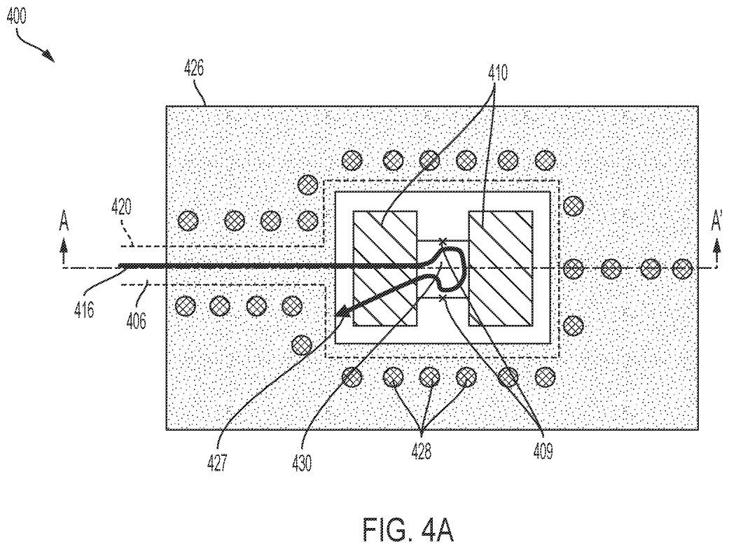

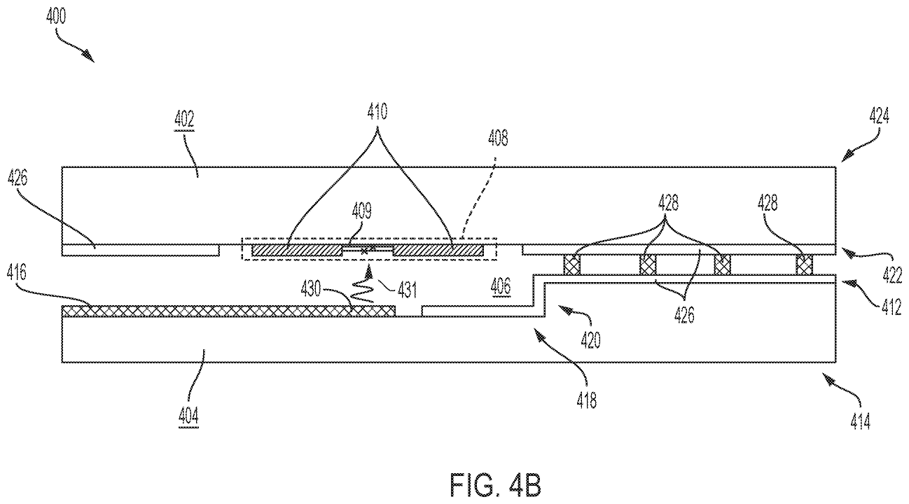

As shown in FIG. 2, the cap wafer 212 includes a first surface 234 and a second, opposite surface 236. Each of the recesses 232 is defined by a recessed surface 238 and sidewalls 240. The recessed surface 238 is located at a depth in the cap wafer 212 relative to the first surface 234. In some implementations, each of the recesses 232 may be a cavity, a shallow trench, a deep trench, or in another form. Dimension and shape of a recess 232 may be determined according to the dimension and shape of the quantum circuit device 204 or the superconducting circuit 206 associated with or enclosed by the recess. For example, a recess 232 in a form of a cavity can be used to form an enclosure to a quantum circuit device 204; and a recess 232 in a form of a shallow trench may be used to form an enclosure to a control line (e.g., the control line 416 as shown in FIGS. 4A-4B). As shown in FIG. 2, each of the recesses 232 has vertical sidewalls 240 along the Z-direction perpendicular to the first and second surfaces 234, 236. In certain implementations, the recesses 232 may include angled or sloped sidewalls 240 between the first surface 234 and the recessed surface 238.

As shown in FIG. 2, the recesses 232 are defined on the first surface 234 of the cap wafer 212 at positions corresponding to the quantum circuit devices 204 or the superconducting circuit 206 disposed on the device wafer 202. In this manner, the device wafer 202 and the cap wafer 212 are arranged such that a recess 232 of the cap wafer 212 forms an enclosure that houses a respective quantum circuit device 204. A depth of the recessed surface 238 relative to the first surface 234 (e.g., a vertical distance between the first surface 234 and the recessed surface 238) of each recess 232 can be in a range of 5-500 μm. A lateral dimension of a recess 232 along the X axis or the Y axis is greater than a respective quantum circuit device 204 enclosed by the recess 232. In some instances, the lateral dimension of a recess 232 may be determined by another design parameter. For example, in order to suppress propagation of electromagnetic waves with a frequency less than a cut off frequency inside a recess 232, the lateral dimension of the recess 232 can be determined as a value which is less than a maximal distance corresponding to the cutoff frequency.

In some implementations, the depth of each recess 232 can determine a participation ratio of the electric fields around the quantum circuit device 204. A participation ratio can be adjusted to tune the coherence time of the quantum circuit device 204. Instead of having the fields mostly in the first substrate which has an RF loss, a ground plane can reside on the recessed surface 238 in the cap wafer 212. In some instances, the distances between the ground plane and the quantum circuit device 204 can be controlled allowing some of the electric field between the ground plane and the quantum circuit device 204 to be confined in the space defined by the recess 232, rather than in the lossy first substrate 203 of the device wafer 202. For example, the participation ratio can be controlled by tuning the depth of the recess 232 of the cap wafer 212 as compared to the thickness of the device wafer 202.

In certain implementations, the depth of each of the recesses 232 can be determined according to a desired coupling between the circuitry on the recessed surface 238 and the quantum circuit device 204 on the surface of the device wafer 202. In some instances, the first and second substrates 203, 213 may have a high permittivity to reduce capacitive cross-talk between the superconducting circuit 206 and the circuitry portions 214, 216 as the electric fields stay localized in the first and second substrates 203, 213, respectively.

As shown in FIG. 2, the cap wafer 212 is bonded to the device wafer 202 using bonding bumps 224. In some implementations, each of the bonding bumps 224 may include conductive or superconductive materials, such as copper or indium bumps. The cap wafer 212 is bonded with the device wafer 202 with the first surface 234 facing the surface of the device wafer 202 on which the quantum circuit devices 204 and the superconducting circuit 206 are disposed. In some implementations, the bonding bumps 224 can provide electrical communication of the superconducting circuit 206 on the device wafer 202 with the various circuitry portions (e.g., 214, 216, 218, and 220) on the cap wafer 212. The gap between the first surface 234 of the cap wafer 212 and the surface where the quantum circuit devices 204 reside on the device wafer 202 is determined by the height of the bonding bumps 224. In some implementations, the height of the bonding bumps can be controlled by the thickness of the bonding bumps initially deposited on the cap wafer 212 and the bonding process. For example, the gap between the cap wafer 212 and the device wafer 202 is equal to or less than 3 μm, or in another range.

In some instances, adjacent quantum circuit devices 204 disposed on the device wafer 202 can be coupled through a coupling line as a part of the superconducting circuit 206 extending along the surface of the device wafer 202 over at least a portion of the distance between the adjacent quantum circuit devices 204. The coupling between the adjacent quantum circuit devices 204 can be capacitive or direct. In some instances, at least a portion of the coupling line can also be encapsulated by a respective recess 232 in the cap wafer 212. In some implementations, multiple quantum circuit devices 204 can form a lattice, in which all or a subset of the quantum circuit devices 204 (e.g., each qubit device) in the lattice are coupled to one or more neighboring quantum circuit devices 204. In some implementations, a lattice may be coupled to one or more neighboring lattices.

In some implementations, the circuitry portions 214, 216, 218, 220 on the cap wafer 212 may include a variety of circuit elements to control or readout the quantum circuit devices 204 on the device wafer 202. For example, the circuitry portion 216 includes flux bias lines which can provide magnetic flux locally to qubit devices to tune their frequencies. In this case, the circuitry portion 216 may be implemented as the circuitry shown in FIGS. 4A, 4B, or in another manner. The circuitry portion 216 may also include tunable coupler devices, and microwave feedlines. The circuitry portion 216 on the recessed surface 238 may include resonator devices which are capacitively coupled to qubit devices to readout qubits. In some examples, the circuitry portion 216 may include microwave feedlines which are coupled to one or several of the resonator devices to allow microwave excitation of the resonator devices used to readout qubits. In this case, the circuitry portion 216 may be implemented as the planar resonators 504 shown in FIG. 5. The circuitry portion 214 on the first surface 234 of the cap wafer 212 may include microwave lines which are capacitively coupled to qubit devices to drive qubits. The circuitry portion 220 on the second surface 236 or the circuitry portion 214 on the first surface 234 of the cap wafer 212 may further include filters, isolators, circulators, amplifiers, or other circuit elements.

In some implementations, the circuitry portion 216 on the recessed surface 238 may be coupled to the circuitry portion 214 on the first surface 234 and the circuitry portion 220 on the second surface 236 through conductive pathways. For example, the circuitry portion 216 can be galvanically coupled to the circuitry portion 214 through conductive lines 218 disposed or patterned on sidewalls 240 of the recess 232. In some instances, each of the conductive lines 218 includes a patterned metal coating that covers a portion of the sidewalls 240 extending from the recessed surface 238 to the first surface 234. In certain examples, each of the conductive lines 218 include an unpatterned metal coating that covers the entire sidewalls 240. For another example, the circuitry portion 216 may be electrically coupled to the circuitry portion 214 through the conductive vias 222A, 222B and the circuitry portion 220 on the second surface 236. In some instances, the circuitry portion 216 and the circuitry portion 214 may be coupled in another manner. In some instances, the circuitry portion 214 on the first surface 234 of the cap wafer 212 can be capacitively and/or inductively coupled to the circuitry portion 216 on the recessed surface 238 of the cap wafer, for example, using an interdigitated capacitive coupler device. In other instances, the circuitry portions 214 and 216 may be inductively coupled. For example, the circuitry portions 214 and 216 including coplanar waveguides may be arranged next to each other so as to be inductively coupled. For example, the circuitry portion 216 may include a bias tee or a diplexer circuit containing capacitive and/or inductive coupling components which is used to combine a high-frequency XY qubit control signal with a low-frequency flux bias control signal received from the circuitry portion 214.

In some instances, the circuitry portions 214 and 216 can be coupled through one or more electrically conductive vias 222. For example, the circuitry portion 214 may be connected to an electrically conductive via 222A to the circuitry portion 220 on the second surface 236, which is further connected to the circuitry portion 216 through another electrically conductive via 222B. A capacitance coupling between the two circuitry portions 214, 216 can be achieved by introducing a thin dielectric layer along the radial or the axial direction in one of the electrically conductive vias 222A or 222B. When the thin dielectric layer is disposed along the radial direction of the electrically conductive via, the thin dielectric layer can be sandwiched between top and bottom sections of the conductor in a via hole. In some instances, the thin dielectric layer may reside on one end of the electrically conductive via 222A or 222B. When the thin dielectric layer is disposed along the axial direction of the electrically conductive via, (e.g., a coaxially filled via hole), the thin dielectric layer may be sandwiched between an outer cylinder-shaped conductor and an inner cylinder-shaped conductor.

As shown in FIG. 2, a circuitry portion 228 is formed on the recessed surface 238 and the sidewalls 240. In some implementations, the circuitry portion 228 can be used as a Faraday cage, which can prevent stray electric fields from reaching the quantum circuit device 204. In some implementations, when the circuitry portion 228 contains superconducting materials, the circuitry portion 228 may also be used to exclude stray magnetic fields from reaching the quantum circuit device 204.

In some implementations, the circuitry portions on the cap wafer 212 may be formed in one or more electrically conductive layers on the first surface 234, the second surface 236, or the recessed surface 238. In some instances, the one or more electrically conductive layers may cover at least a portion of sidewalls 240 of each of the recesses 232. In other implementations, each of the one or more electrically conductive layers may include a material that has normal conductance at the operating temperature of the example quantum processing unit 200. In some implementations, the example quantum processing unit 200 can be operated at cryogenic temperatures (e.g., cooled using liquid helium) and each of the one or more electrically conductive layers (or at least a portion) can operate as a superconducting layer at that temperature. In addition, during operation of the example quantum processing unit 200, at least a portion of the one or more electrically conductive layers in the various superconducting circuitry of the cap wafer 212 can be grounded.

As shown in FIG. 2, the cap wafer 212 includes electrically conductive vias 222 (e.g., via holes filled with conductive materials) each extending through the second substrate 213. A first length of the electrically conductive vias 222A along the Z axis corresponds to a thickness of the second substrate 213, which can be in the range of 1 μm to 2 mm. A second length of the electrically conductive vias 222B along the Z axis corresponds to a difference between the thickness of the second substrate 213 and the depth of the recess 232. In some implementations, the electrically conductive vias 222A, 222B include a material (e.g., Al, In, Ti, Pn, Sn, etc.) that is superconducting at an operating temperature of the example quantum processing unit 200.

As shown in FIG. 2, the electrically conductive via 222A provides an electrical connection between the circuitry portion 214 on the first surface 234 and the circuitry portion 220 on the second surface 236. In some implementations, this enables both outside connections to land on the second surface 236 (e.g., unbonded side) of the cap wafer 212 and then connect to the first surface 234 (e.g., bonded side) and from there down to the superconducting circuit 206 and further to the quantum circuit devices 204, for example, through the bonding bumps 224. The electrically conductive via 222B provides an electrical connection between the circuitry portion 220 on the second surface 236 and the circuitry portion 216 on the recessed surface 238. In some implementations, the electrically conductive vias 222A, 222B can be used to form a continuous ground plane through the example quantum processing unit 200, such that a solidly connected ground plane can be maintained across both the device wafer 202 and the cap wafer 212. Multiple electrically conductive vias 222A, 222B connected to the ground planes located on the first and second surfaces 234, 236 of the cap wafer 212, and the recessed surface 238 may be arranged in a regular array to avoid a formation of a chip-mode resonance and to mitigate unwanted modes (e.g., coupled slotline mode, parallel-plate waveguide modes, or resonant patch mode). For example, such a regular array of electrically conductive vias connected to the ground planes can push dielectric chip modes with the cap wafer 212 to higher frequencies.

In some instances, quantum circuit devices 204 may be coupled via alternative signal routing levels provided by the circuitry portions 214, 216, 220, the conductive lines 218, and the electrically conductive vias 222A, 222B on the cap wafer 212. For example, non-neighboring quantum circuit devices 204 without qubit-to-qubit connections (e.g., direct coupling lines on the device wafer 202) may be provided by the cap wafer 212. In some implementations, the circuitry portion 214 may be coupled to the superconducting circuit 206 using capacitive, inductive, or galvanic connections. In some instances, the circuitry portions 214, 216, 220 may include planar transmission lines, for example coplanar waveguides, substrate integrated waveguides or another type of planar transmission line.

In some implementations, a subset of the one or more electrically conductive vias 222 are electrically coupled with control lines to supply control signals to, or coupled with other signal lines to retrieve readout signals from, the quantum circuit devices 204 of the quantum processing unit 200. For example, the control signals can be provided to the device wafer 202 from a signal delivery system (e.g., the signal delivery system 106 of the quantum computing system 100) or the readout signals can be retrieved from the quantum circuit devices 204 to the signal delivery system. In some implementations, a subset of the one or more electrically conductive vias 222A, 222B may be grounded to provide ground to electrically coupled circuitry portions. In some instances, the one or more electrically conductive vias 222A, 222B may include another subset that can be used for thermalization. In this case, the cap wafer 212 allows better heatsinking of the quantum circuit devices 204 to the refrigeration system using the one or more electrically conductive vias 222A, 222B as thermal paths for heat dissipation. The methods and techniques presented here can reduce losses in the quantum circuit devices 204.

In some instances, the second surface 236 of the cap wafer 212 can be coated with a material with a low thermal emissivity, which can reduce the heat load on the quantum circuit devices 204 by reflecting infra-red thermal radiation emitted by the surrounding components. For example, the ground plane on the second surface 236 of the cap wafer 212 can be coated with, or otherwise include the material with a low thermal emissivity. The material with a low thermal emissivity may include a thin layer of superconductive or non-superconductive metal, e.g., gold (Au), palladium (Pd), platinum (Pt), Al, and Ti.

FIG. 3A is a schematic diagram of an exploded view of an example quantum processing unit 300. The example quantum processing unit 300 includes multiple device dies 302 (e.g., 302A, 302B, and 302C) and a cap wafer 304. The cap wafer 304 includes multiple recesses 310 and each of the device dies 302 includes four qubit devices 306 and two tunable coupler devices 308. As shown in FIG. 3A, two neighboring qubit devices 306 are coupled together through a tunable coupler device 308. The qubit device 306 can be capacitively coupled to the tunable coupler 308 through a capacitor. As shown in the example quantum processing unit, the device dies 302 and the cap wafer 304 are arranged such that recesses 310 of the cap wafer 304, when the device dies 302 and the cap wafer 304 are bonded together, form enclosures that house the qubit devices 306 and the tunable coupler device 308 of the device dies 302. In some implementations, the example quantum processing unit 300 may include additional and different features or components and components of the example quantum processing unit 300 may be implemented in another manner.

In some implementations, the tunable coupler device 308 may be implemented as a tunable-frequency transmon qubit device. For example, the tunable coupler device 308 includes two Josephson junctions connected in parallel with each other to form a circuit loop, which resides adjacent to a control line. The tunable coupler device 308 may also include other circuit components. A control line can receive control signals, for example, from an external control system (e.g., the control system 105 of FIG. 1). In some instances, the control line can include, for example, a flux bias device that is configured to apply an offset magnetic field to the tunable coupler device 308. For instance, the flux bias device may include an inductor that has a mutual inductance with the circuit loop of the tunable coupler device 308. The control line may be located at a recessed surface of the recesses 310 on the cap wafer 304. In some implementations, the effective coupling between the two qubit devices 306 can be controlled or actuated by tuning a magnetic field applied to the tunable coupler device 308. For example, a control signal (e.g., a DC or an AC current) can be applied to a control line to tune the magnetic flux threading to the circuit loop of the tunable coupler device 308 to turn on or off the coupling.

In some examples, the qubit device 306 may be implemented as a fixed-frequency transmon qubit device. For example, a qubit device 306 may include a Josephson junction and a capacitor which are connected in parallel. In some instances, the qubit device 306 may be implemented as a tunable qubit device. In this case, the qubit device 306 may include one or more tunable transmon qubit devices or tunable fluxonium qubit devices. In some implementations, the qubit device 306 may include another type of tunable qubit device. When the qubit device 306 is a tunable qubit device, the transition frequency of the tunable qubit device can be controlled by a magnetic flux provided by a separate control line on the cap wafer 304. In some instances, the transition frequency may be controlled in another manner, for instance, by another type of control signal. In some implementations, the control line may be coupled (e.g., conductively, capacitively, or inductively) to a control port to receive control signals.

FIG. 3B is a schematic diagram of a perspective view of an example quantum processing unit 320. The example quantum processing unit 320 includes multiple device dies 322 and a cap wafer 324. The cap wafer 324 includes multiple recesses 330 and each of the device dies 322 includes eight qubit devices 332. Each of the qubit devices 332 is conductively connected to a respective electrode 334. For example, as shown in FIG. 3B, a first qubit device 332A in the device die 322A is galvanically connected to a first electrode 334A and a second qubit device 332B in the device die 322B is galvanically connected to a second electrode 334B. As shown in the example quantum processing unit 320, the device dies 322 and the cap wafer 324 are arranged such that recesses 330 of the cap wafer 324, when the device dies 322 and the cap wafer 324 are bonded together, form enclosures that house the qubit devices 332 of the device dies 322. In some implementations, the example quantum processing unit 320 may include additional and different features or components and components of the example quantum processing unit 320 may be implemented in another manner.

As shown, the cap wafer 324 includes multiple inter-chip coupler arrays 326 (e.g., 326A, 326B, and 326C), which, when the device dies 322 and the cap wafer 324 are bonded together, is configured to provide inter-chip coupling. The inter-chip coupler arrays 326 may be configured as shown in FIG. 3B or in another manner. Each of the inter-chip coupler arrays 326 is configured to provide coupling between qubit devices 306 on different device dies 322. As shown in FIG. 3B, the inter-chip coupler array 326A is configured to communicably couple the qubit devices 332 on the device die 322A and on the device die 322B; the inter-chip coupler array 326B is configured to communicably couple the qubit devices 332 on the device die 322B and on the device die 322C; and the inter-chip coupler array 326C is configured to communicably couple the qubit devices 332 on the device die 322C and on the device die 322D.

In some instances, the inter-chip coupler array 326 may be configured to communicably couple qubit devices 332 of device dies 322 that are not adjacent to each other. For example, an inter-chip coupler array 326 may include one or more inter-chip coupler devices 328 that can extend or be routed across the cap wafer 324 to provide coupling between qubit devices 332 on the device die 322A and 322C or 322D. In this case, an inter-chip coupler device 328 may be routed on a surface of the cap wafer 324, recessed surfaces and/or sidewalls of the recesses 330 of the cap wafer 324.

As shown in the example quantum processing unit 320, each of the inter-chip coupler devices 328 includes a conductive line 338 and two electrodes 336A, 336B. The device dies 322 and the cap wafer 324 are arranged such that each of the two electrodes 336A, 336B of the inter-chip coupler device 328 form a coupling with respective electrodes 334 of respective qubit devices 332. For example, the coupling can be capacitive through a gap separating the two respective electrodes (e.g., 334A of the qubit device 332A and 336A of the inter-chip coupler device 328). For example, the coupling can be conductive through one or more bonding bumps 340 galvanically connecting the two respective electrodes (e.g., 334A of the qubit device 332A and 336A of the inter-chip coupler device 328). In some instances, the coupling between the inter-chip coupler 328 and the qubit device 332 is inductive. For example, the electrodes 336 of the inter-chip coupler 328 may be configured as an inductor that has a mutual inductance with a circuit loop in a qubit device 332A of a device die 322. In some instances, the inter-chip coupler device 328 may be implemented as the control line 416 and the planar loop 430 of the control line 416 shown in FIGS. 4A-4B or in another manner.

FIGS. 4A-4B are schematic diagrams of top view and cross-sectional view of an example quantum processing unit 400. The example quantum processing unit 400 includes a device wafer 402 and a cap wafer 404. As shown in FIGS. 4A-4B, the cap wafer 404 includes a first surface 412 and a second surface 414; and the device wafer 402 includes a first surface 422 and a second surface 424. The first surface 412 of the cap wafer 404 and the first surface 422 of the device wafer 402 face each other and are bonded together by bonding bumps 428. The device wafer 402 includes a quantum circuit device 408 residing on the first surface 422. The cap wafer 404 includes a planar loop 430 as part of a control line 416. The planar loop 430 interacts with the quantum circuit device 408 on the device wafer 402 (e.g., the SQUID loop 409 of the quantum circuit device 408) to generate and control a local magnetic flux threading the SQUID loop 406. In some instances, the planar loop 430 of the control line 416 may be implemented as a single-turn loop, a multi-turn loop, or in another form. The control line 416 is disposed in a recess 406, which is defined by a recessed surface 418 and sidewalls 420. One end 427 of the control line 416 (as indicated by the arrow at one end of the control line 416) is galvanically connected to ground plane 426 on the cap wafer 404. The cap wafer 404 may further include various superconducting circuitry disposed at various surfaces of the cap wafer 404. For example, the device wafer 402 and the cap wafer 404 may be implemented as the device wafer 202 and the cap wafer 212 in FIG. 2. In some implementations, the example quantum processing unit 400 may include additional and different features or components and components of the example quantum processing unit 400 may be implemented in another manner.

The methods and techniques disclosed here can reduce unpredictable, non-localized interactions between different elements of a superconducting circuit, which are caused by a propagation of superconducting currents (e.g., supercurrents) in thin films. Supercurrents run along edges of thin films due to the Meissner effect which can cause flux crosstalk between qubit devices at different locations. For example, when a current signal is applied on a flux bias line at a first location, a supercurrent can generate a small bias flux at a second, distinct location. The methods and techniques presented here can effectively sink and remove supercurrents that are circulating around quantum circuit devices, reduce unwanted flux crosstalk, and reduce the coherent error, for example in two-qubit gates of superconducting quantum computers.

As shown in FIGS. 4A-4B, ground planes 426 on the first surface 422 of the device wafer 402 and the first surface 412 of the cap wafer 404 are bonded together by the bonding bumps 428. In some implementations, the cap wafer 404 can reduce flux crosstalk by guiding the supercurrents from the ground planes 426 on the device wafer 402 to the bonding bumps 428, which supercurrents can be collected by and dispersed at the ground plane 426 on the cap wafer 404. In other words, the ground plane 426 on the cap wafer 404 along with the selective placement of the bonding bumps 428 provides an opportunity to segment the ground plane. In some instances, segments of ground planes created can be kept at an equipotential.

In some implementations, the quantum circuit device 408 disposed on the first surface 422 of the device wafer 402 may be implemented as the quantum circuit device 204 as shown in FIG. 2 including qubit devices, or another type of quantum circuit device. As shown in FIGS. 4A-4B, the quantum circuit device 408 is configured as a tunable transmon qubit device with qubit electrodes 410 and two Josephson junctions forming a Superconducting Quantum Interface Device (SQUID) loop 409. The qubit electrodes 410 are configured to form a shunt capacitor in parallel with the two Josephson junctions. In some instances, the qubit electrodes 410 of the quantum circuit device 408 may be configured to capacitively couple to other circuit components in the cap wafer 404 and the device wafer 402, for example, the planar loop 430 of the control line 416 on the cap wafer 404 and the ground plane 426 on the device wafer 402. The SQUID loop 409 and the qubit electrodes 410 containing superconducting materials are surrounded by the ground planes 426 on the first surface 422 of the device wafer 402.

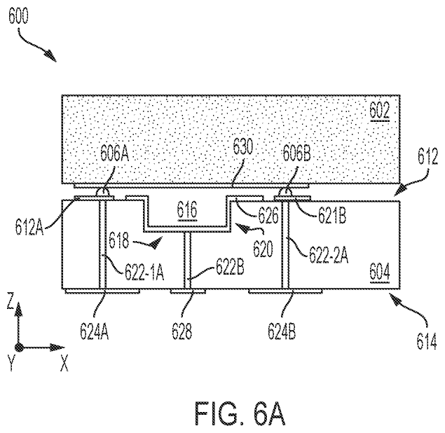

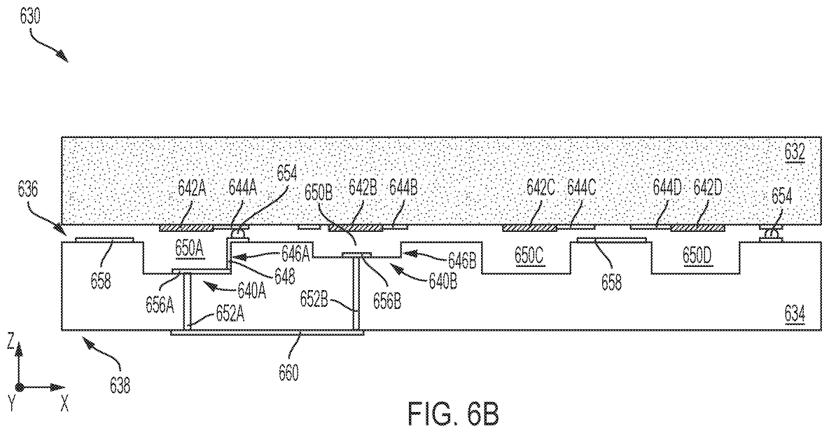

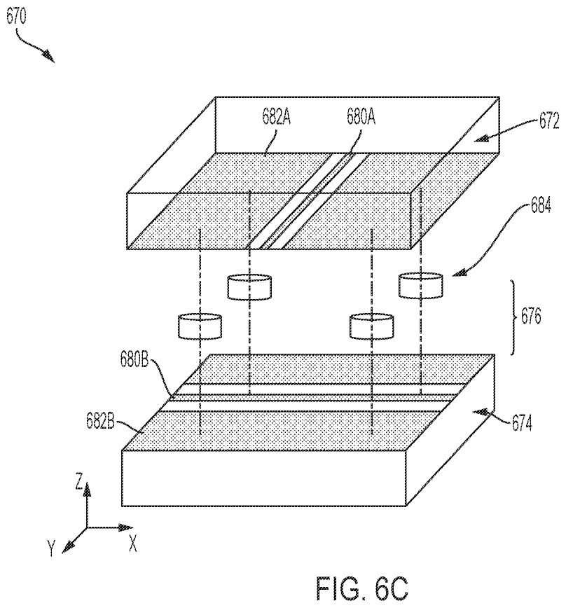

In some implementations, the control line 416 on the recessed surface 418 of the recess 406 on the cap wafer 404 includes conductor metal that carries a control signal to and from the quantum circuit device 408 or other quantum circuit devices on the device wafer 402. In some instances, the control line 416 is a planar transmission line (e.g., coplanar waveguides, substrate integrated waveguides or another type of planar transmission line). For example, the control line 416 may be implemented as the coplanar waveguides shown in FIG. 6C.

In some examples, the control line 416 is a flux bias line. In this case, the planar loop 430 is inductively coupled to the SQUID loop 409, the frequency of the quantum circuit device 408 can be tuned by applying a magnetic field 431 through the SQUID loop 409. The magnetic field 431 can be generated by the flux bias line. The desired mutual inductance can be achieved by adjusting the distance between the flux bias line and the SQUID loop 409. In some cases, the distance between the flux bias line and the SQUID loop 409 is defined by the depth of the recess 406 and the height of the bonding bumps 428. For example, the distance is in a range of 10-20 μm, or may be in another range. In some instances, the value of the mutual inductance is in a range of 400-800 femto Henry (fH), or in another range.

In some examples, the control line 416 is a microwave line. In this case, the control line 416 is capacitively coupled to the quantum circuit device 408 on the device wafer 402, for example through the qubit electrodes 410. The capacitive coupling between the quantum circuit device 408 and the control line 416 can be set by the relative positions and distance of the cap wafer 404 and the device wafer 402. The state of the quantum circuit device 408 can be manipulated by sending microwave pulses along the control line 416. In some instances, the distance between the control line 416 and the quantum circuit device 408 is equal to or greater than a threshold distance, e.g., around 50-200 μm. In some instances, the capacitive coupling is in a range of 0.1-0.5 femto Farad (fF), or in another range.

In some instances, the control line 416 which is capacitively and inductively coupled to the quantum circuit device 408 can simultaneously serve as a flux bias line and a microwave line. In this case, the control signal on the control line 416 can include a low-frequency component (e.g., typically with a highest frequency value up to ˜500 MHz or a different value) and a high-frequency component at or near the qubit frequency (e.g., typically about 4 GHz or a different value). The low-frequency component in the planar loop 430 generates a local magnetic field that interacts with the SQUID loop 409 of the quantum circuit device 408 and tunes the frequency of the quantum circuit device 408. In this case, the low-frequency component of the current bias is a flux bias signal. The high-frequency component interacts capacitively with the qubit electrodes 410 of the quantum circuit device 408 and causes the wavefunction in the qubit to change in a controlled fashion. The high-frequency component of the current bias is a microwave drive signal.

The methods and devices presented here can allow independent tuning of both the capacitive and magnetic coupling, both of which have to be correctly targeted to get correct operation. The ability to tune both capacitive and magnetic coupling independently allows combined flux bias and microwave lines to be integrated into the cap wafer 404. In some implementations, by moving these circuit elements from the device wafer 402 to the cap wafer 404, the capacitive coupling is significantly reduced since the planar loop 430 of the control line 416 to the quantum circuit device 408 are separated by vacuum with a lower permittivity relative to that of a substrate of the device wafer 402 (e.g., a silicon substrate).

FIG. 5 is a schematic diagram of a top view of an example cap wafer 500. The example cap wafer 500 includes multiple planar resonators 504 coupled to a feedline 502. As shown in FIG. 5, the multiple planar resonators 504 and the feedline 502 have a coplanar waveguide structure, which includes a central conductive line and a ground plane. In some instances, the feedline 502 and the planar resonators 504 may include another type of planar transmission line, for example, a microstrip transmission line or a substrate integrated waveguide. Each of the planar resonators 504 is inductively coupled to the central conductive line of the feedline 502. In some implementations, the feedline 502 allows multiplexing the multiple planar resonators 504 on the cap wafer 500. In some implementations, the cap wafer 500 may include additional and different features or components and components of the example cap wafer 500 may be implemented in another manner.

As shown in FIG. 5, each of the planar resonators 504 and the feedline 502 resides on recessed surfaces 506 of respective recesses 508 of a substrate. In some instances, the planar resonators 504 and the feedline 502 on the recessed surface 506 may be implemented as part of the circuitry portion 216 on the recessed surface 238 of the cap wafer 212 shown in FIG. 2 or in another manner. In some implementations, the planar resonators 504 and the feedline 502 are superconducting microwave devices operating in the microwave frequency domain in a cryogenic environment. In some implementations, the feedline 502 and the planar resonators 504 may be used as a readout resonator for receiving a readout signal from a qubit device on a device wafer. As shown, the feedline 502 includes two ports 510A, 510B. For example, a readout signal can be received on the port 510A and an output signal can be obtained at the port 510B.

As shown in the example cap wafer 500, the central conductive lines of the planar resonators 504 are shaped in a meander-like structure. Each of the planar resonators 504 is inductively coupled to the feedline 502 via a respective arm 512 which is adjacent and parallel to the central conductive line of the feedline 502. Each of the planar resonators 504 includes parallel segments forming intra-line capacitors.

In some implementations, the recesses 508 may be implemented as the recesses 232 shown in FIG. 2 and formed by performing the operations 802, 804, and 806 in the example process 800 shown in FIG. 8 or in another manner. In some implementations, the central conductive line and the ground planes of the feedline 502 and the planar resonators 504 include superconductive materials. For example, the feedline 502 and the planar resonator 504 may be formed on the recessed surfaces 506 as part of the second circuitry portion 842B by performing the operations 808, 810, and 812 of the example process 800 shown in FIG. 8. In some instances, the feedline 502 and the planar resonators 504 may be formed in another manner.

In certain examples, the internal resonator property of each of the planar resonators 504, such as the resonant frequency, loss, signal-to-noise ratio, quality factor, are determined by physical parameters of the planar resonators 504. In some implementations, the central conductive lines of the planar resonators 504 may have different physical dimensions, e.g., total length, width, thickness and number of turns of the central conductive lines of the planar resonators 504, length of parallel segments of the planar resonators 504, distance between the central conductive line and the ground plane, length of the arm 512 for inductively coupling with the feedline, dielectric properties of the substrate, and depth of the recesses 508. In some implementations, each of the planar resonators 504 can be designed and optimized individually with different internal resonator properties. In some instances, the external quality factor depends on characteristics of the planar resonator 504, the coupling strength between the planar resonator 504 and the feedline 502, and impedance of the two ports 510A, 510B.

FIG. 6A is a schematic diagram of a cross-sectional view of an example quantum processing unit 600. The example quantum processing unit 600 includes a device wafer 602 and a cap wafer 604. As shown in FIG. 6A, the cap wafer 604 includes a first surface 612 and a second surface 614. The device wafer 602 and the cap wafer 604 are bonded together using bonding bumps 606A, 606B. The cap wafer 604 shown in FIG. 6A further includes a recess 616, which is defined by a recessed surface 618 and sidewalls 620.

In some implementations, the cap wafer 604 may include circuitry portions on the first, second surfaces 612, 614 and the recessed surface 618 providing different functionalities. In some instances, the first and second surfaces 612, 614 of the cap wafer 604 may be implemented as the first and second surfaces 234, 236 of the cap wafer 212 shown in FIG. 2 or in another manner. In the example shown in FIG. 6A, the first surface 612 includes circuitry portions 621A, 621B; and the second surface 614 includes circuitry portions 624A, 624B and 628. As shown in FIG. 6A, the circuitry portion 626 resides on the cap wafer 614 covers a portion of the first surface 612, the recessed surface 618, and the sidewalls 620.

In some implementations, the circuitry portions on different surfaces can be electrically connected and routed to feed control signals to or transfer readout signals from the device wafer 602. As shown in the example quantum processing unit 600, the circuitry portions 624A, 624B on the second surface 614 of the cap wafer 604 are electrically coupled to the circuitry portions 621A and 621B on the first surface 612 of the cap wafer 604 through respective conductive vias 622-1A, 622-2A. The circuitry portions 621A, 621B on the first surface 612 are electrically coupled to a superconducting circuit 630 on a surface of the device wafer 602 using respective bonding bumps 606A, 606B. The circuitry portion 628 on the second surface 614 of the cap wafer 604 is electrically coupled to the circuitry portion 626 through the conductive vias 622B. In some implementations, the circuitry portions 628 and 626 can be grounded.

In some instances, the conductive vias 622-1A and 622-2A may be implemented as the conductive vias 222A shown in FIG. 2 or in another manner. In some instances, the conductive vias 622B may be implemented as the conductive vias 222B shown in FIG. 2 or in another manner. In certain instances, the bonding bumps 606A, 606B may be implemented as the bonding bumps 224 shown in FIG. 2 or in another manner.

In some implementations, during operation, the circuitry portion 624A on the second surface 614 of the cap wafer 604 may receive control signals from a control system (e.g., the control system 105 of the computing system 101 shown in FIG. 1). The control signal can be then directed across the conductive via 622-1A to the circuitry portion 621A on the first surface 612. The control signal can be then directed to the superconducting circuit 630 on the device wafer 602 through the bonding bump 606A. Similarly, a readout signal from the superconducting circuit 630 on the device wafer 602 can be directed to the circuitry portion 621B on the first surface 612 of the cap wafer 604 using the bonding bump 606B. The readout signal can be then directed across the conductive via 622-2A to the circuitry portion 624B on the second surface 614 and eventually received by the control system.

FIG. 6B is a schematic diagram of a cross-sectional view of an example quantum processing unit 630. The example quantum processing unit 630 includes a device wafer 632 and a cap wafer 634. In some implementations, the device wafer 632 and the cap wafer 634 may be implemented as the device and cap wafers 202, 204 shown in FIG. 2 or in another manner. As shown in FIG. 6B, the device wafer 632 and the cap wafer 634 are bonded together using bonding bumps 654.

As shown in FIG. 6B, the device wafer 632 includes four quantum circuit devices 642A, 642B, 642C and 642D disposed on the surface of the device wafer 632. Each of the quantum circuit devices 642A, 642B, 642C and 642D may be electrically coupled to a respective portion of a superconducting circuit 644A, 644B, 644C or 644D. Specifically, a first quantum circuit device 642A is electrically coupled to a first portion of a superconducting circuit 644A; a second quantum circuit device 642B is electrically coupled to a second portion of a superconducting circuit 644B; a third quantum circuit device 642C is electrically coupled to a third portion of a superconducting circuit 644C; and a fourth quantum circuit device 642D is electrically coupled to a fourth portion of a superconducting circuit 644D. In some implementations, the quantum circuit devices 642 and the superconducting circuit 644 may be implemented as the quantum circuit device 204 and the superconducting circuit 206 shown in FIG. 2 or in another manner.

As shown in FIG. 6B, the cap wafer 634 includes a first surface 636 and a second surface 638. The cap wafer 634 includes four recesses 650A, 650B, 650C and 650D. In some implementations, each of the four recesses 650A, 650B, 650C and 650D can be implemented as the recess 232 shown in FIG. 2 or in another manner. As shown in example quantum processing unit 642A, 642B, 642C and 642D, each of the four recesses 650A, 650B, 650C and 650D on the cap wafer 634 encloses a respective quantum circuit device 642A, 642B, 642C or 642D on the device wafer 632.

In the example shown in FIG. 6B, a first recess 650A is defined by a first recessed surface 640A and sidewalls 646A; and a second recess 650B is defined by a second recessed surface 640B and sidewalls 646B. As shown in FIG. 6B, the first recessed surface 640A resides at a first depth in the cap wafer 634 relative to the first surface 636 and the second recessed surface 640B resides at a second depth in the cap wafer 634 relative to the first surface 636. The first depth is greater than the second depth. In certain instances, the first and second depths may have another relationship.

In some implementations, the cap wafer 634 includes circuitry portions on its first, second, and recessed surfaces 636, 638 and 640. In the example quantum processing unit 630, the cap wafer 634 includes a first circuitry portion 658 disposed on the first surface 636, a second circuitry portion 660 disposed on the second surface 638, a third circuitry portion 656A on the first recessed surface 640A, and a fourth circuitry portion 656B on the second recessed surface 640B. In some instances, the first and second circuitry portions 658, 660 may be implemented as the circuitry portion 214 and 220 shown in FIG. 2, or in another manner.

In certain implementations, the circuitry portions disposed at different surfaces of the cap wafer 634 may be galvanically coupled through conductive vias 652 or conductive lines 648 on the sidewalls 646 of the recesses 650. In some implementations, the conductive vias 652 and the conductive lines 648 may be implemented as the respective components 218 and 222 shown in FIG. 2 or in another manner. For example, the third circuitry portion 656A is routed from the first recessed surface 640A through the conductive lines 648 across at least a portion of the sidewalls 646A to the first surface 636, which is galvanically coupled to the first quantum circuit device 642A via the bonding bump 654 and the superconducting circuit 644A. Further, the third circuitry portion 656A is electrically coupled to the second circuitry portion 660 through a first conductive via 652A. Similarly, the fourth circuitry portion 656B is electrically coupled to the second circuitry portion 660 through a second conductive via 652B. As shown in FIG. 6B, the first conductive via 652A extends from the first recessed surface 640A to the second surface 638 of the cap wafer 634; and the second conductive via 652B extends from the second recessed surface 640B to the second surface 638 of the cap wafer 634.

In some implementations, the fourth circuitry portion 656B at the second recessed surface 640B of the second recess 650B may be capacitively coupled to the second quantum circuit device 642B. In some implementations, the capacitive coupling between the second quantum circuit device 642B and the fourth circuitry portion 656B is determined by the distance between the quantum circuit device 642B and the fourth circuitry portion 656B. In some instances, the distance is determined by the height of the bonding bump 654 and the second depth of the second recess 650B. In this case, the first and second quantum circuit devices 642A, 642B, which are not directly coupled, may be coupled together through the first portion of the superconducting circuit 644A, the bonding bump 654, the conductive line 648 on the sidewalls 646A, the third circuitry portion 656A, the conductive via 652A, the second circuitry portion 660, the conductive via 652B, and the fourth circuitry portion 656B. In certain examples, the first and second quantum circuit devices 642A, 642B may be coupled in another manner.

In some implementations, the first circuitry portion 658 on the first surface 636 are capacitively coupled to the superconducting circuit 644 on the device wafer 632. As shown in FIG. 6B, each of the third and fourth portions 644C and 644D of the superconducting circuit are capacitively coupled to the first circuitry portion 658 on the first surface 636 of the cap wafer 634. In this case, the third and fourth quantum circuit device 642C and 642D are coupled through the third portion 644C of the superconducting circuit, the first circuitry portion 658 on the first surface 636 of the cap wafer 634, and the fourth portion 644D of the superconducting circuit. In some implementations, the systems and methods presented here can be used to provide alternative pathways to couple non-neighboring quantum circuit devices 642 on the device wafer 632.

FIG. 6C is a schematic diagram of an exploded view of an example quantum processing unit 670. The example quantum processing unit 670 includes a device wafer 672 and a cap wafer 674. Each of the device wafer 672 and the cap wafer 674 includes a coplanar waveguide. The coplanar waveguide includes a central conductive line and ground planes. In the example quantum processing unit 670, the coplanar waveguide on the device wafer 672 includes a central conductive line 680A and ground planes 682A; and the coplanar waveguide on the cap wafer 674 includes a central conductive line 680B and ground planes 682B.

As shown in the example quantum processing unit 670, each of the device wafer 672 and the cap wafer 674 include a dielectric substrate with a high permittivity. In some instances, the dielectric substrate may be implemented as the substrate 822 shown in FIG. 8 or in another manner. For example, the dielectric substrate may be a silicon substrate with a relative permittivity of 11.68. As shown in FIG. 6C, the coplanar waveguides on the device wafer 672 and the cap wafer 674 extend along the XY plane perpendicular to each other. In some instances, the coplanar waveguides may be arranged in another manner. The ground planes 682A, 682B are galvanically connected using bonding bumps 684. The central conductive lines 680A, 680B are separated by a gap 676 and the thickness of the gap is defined by the height of the bonding bumps 684 or any other additional etched structure in the device wafer 672 and the cap wafer 674. In some implementations, the gap 676 is filled with a low-permittivity material during operation of the quantum processing unit, e.g., vacuum with a relative permittivity of 1, or another type of insulating material with a low permittivity to reduce the coupling (e.g., cross-talk) between the two coplanar waveguides. In some instances, the coupling between the two coplanar waveguides can be further controlled by controlling the gap separating the two coplanar waveguides. For example, the coplanar waveguide on the cap wafer 674 may reside on a recessed surface in a recess.

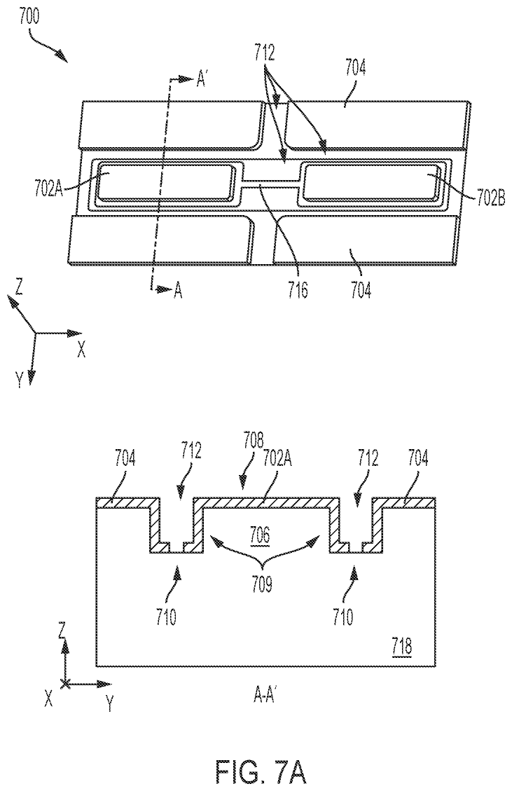

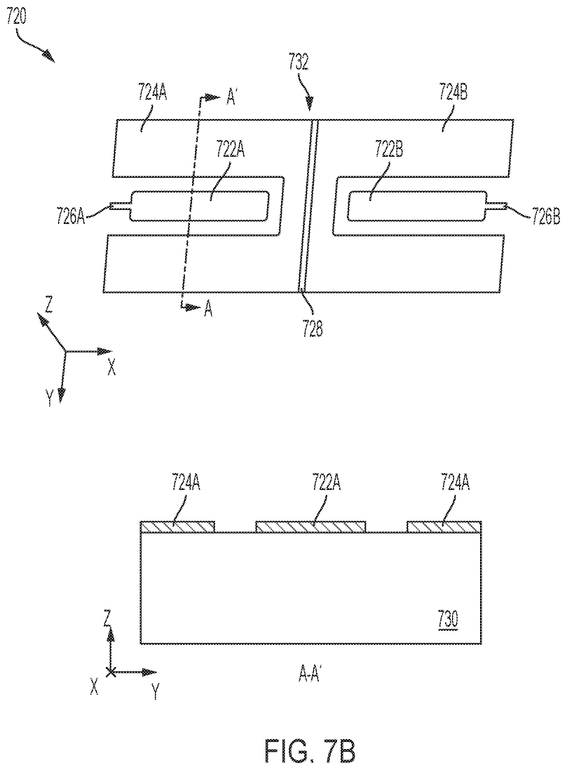

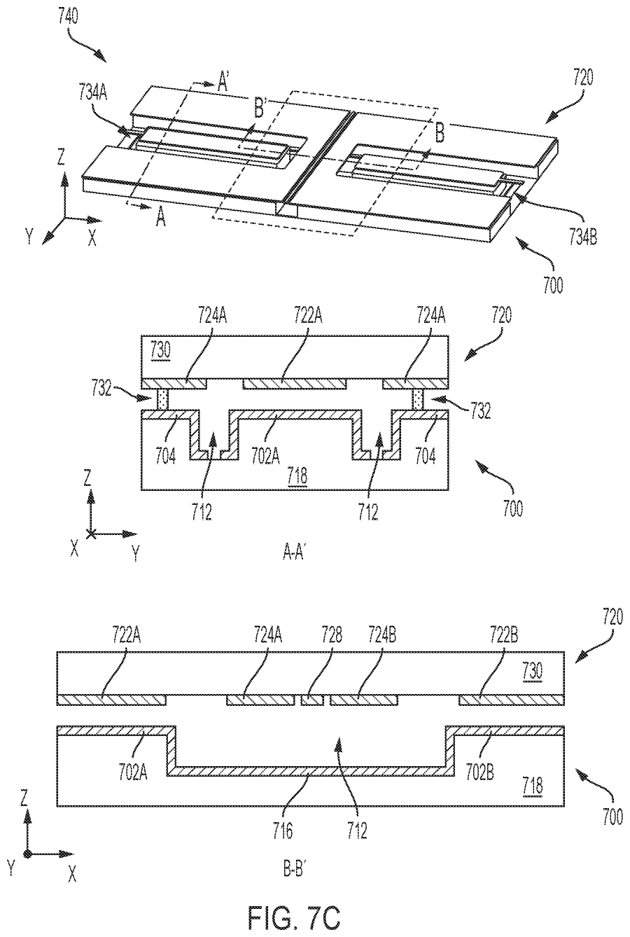

FIG. 7A are schematic diagrams of a perspective view and a cross-sectional view of an example cap wafer 700. The example cap wafer 700 includes two electrodes 702A, 702B, a ground plane 704, and recesses 712, which are formed on a substrate 718. The recesses 712 are defined by recessed surfaces 710 and sidewalls 709. In some instances, the recesses 712 on the substrate 718 may be implemented as the recesses 232 on the substrate 212 shown in FIG. 2 or in another manner. As shown in the example cap wafer 700, the two electrodes 702A, 702B reside on two respective pedestals 706 defined by the surrounding recesses 712.

In some implementations, each of the two electrodes 702A, 702B includes a first portion covering at least a portion of the top surface 708 of the substrate 718, a second portion covering at least a portion of the sidewalls 709 of the recesses 712 around the pedestal 706, and a third portion covering at least a portion of the recessed surfaces 710 of the recesses 712 surrounding the pedestal 706. As shown in FIG. 7A, each of the electrodes 702A, 702B is disposed on the substrate 718 covering the entire top surface 708 of the pedestal 706, and the entire sidewalls 709 of the surrounding recesses 712.

In the example cap wafer 700, the two electrodes 702A, 702B are galvanically connected together via a connection 716 forming a continuous, conductive pathway between the two electrodes 702A, 702B. As shown in FIG. 7A, the connection 716 between the two electrodes 702A, 702B resides on the recessed surface 710 between the two pedestals 706. The two electrodes 702A, 702B are surrounded by a continuous ground plane 704. As shown in FIG. 7A, the ground plane 704 resides on the substrate 718 covering at least a portion of the recessed surface 710, the top surface 708, and the sidewalls 709.

In some implementations, the two electrodes 702A, 702B may be implemented as the circuitry portions on the cap wafer 212 as shown in FIG. 2, or in another manner. In some implementations, the two coupling electrodes 702A, 702B, the pedestals 706, and the recesses 710 may be fabricated according to the example process 800 shown in FIG. 8 or in another manner.

FIG. 7B are schematic diagrams of a perspective view and a cross-sectional view of an example device wafer 720. The example device wafer 720 includes two electrodes 722A, 722B on a substrate 730. As shown in FIG. 7B, the two electrodes 722A, 722B may be connected to two respective quantum circuit devices (e.g., the quantum circuit device 204 in FIG. 2) via respective connections 726A, 726B. In some instances, the two electrodes 722A, 722B and the respective connections 726A, 726B may be implemented as the third and fourth portions 644C and 644D of the superconducting circuit as shown in FIG. 6B. The two respective quantum circuit devices are not directly connected or coupled through a coupling line on the device wafer 720. In some implementations, the example device wafer 720 may include another circuit component.

In some aspects, the techniques disclosed here enable additional signal routing pathways. For example as shown in FIG. 7B, the device wafer 720 includes a coplanar waveguide with a central conductive stripe 728 extending along the y-axis between two ground planes 724A, 724B. The coplanar waveguide separating the two electrodes 722A, 722B and thus the two respective quantum circuit devices on the device wafer 720 may be used, for example, propagating coherent signals between other quantum circuit devices (e.g., tunable coupler device, qubit devices) or other circuit components on the device wafer 720.

FIG. 7C are schematic diagrams of a perspective view and cross-sectional views of an example quantum processing unit 740. The example quantum processing unit 740 includes the example device wafer 720 shown in FIG. 7B and the example cap wafer 700 shown in FIG. 7A. The example quantum processing unit 740 includes two pedestal couplers 734A, 734B. In some implementations, each of the two pedestal couplers 734A, 734B includes a parallel-plate capacitor with one plate on the example cap wafer 700 and the opposite plate on the example device wafer 720. As shown in FIGS. 7A-7C, the example cap wafer 700 and the example device wafer 720 are bonded so that the two electrodes 722A, 722B on the device wafer 720 and the two electrodes 702A, 702B on a cap wafer 700 are aligned with respect to each other. Particularly, the electrodes 702A and 722A form a first pedestal coupler 734A; and the electrodes 702B and 722B form a second pedestal coupler 734B. The two pedestal couplers 734A, 734B are connected in series by the connection 716 on the cap wafer 700.

As shown in FIG. 7C, bonding bumps 732 provide a galvanic connection between the ground planes 724A, 724B on the example device wafer 720 and the ground plane 704 on the cap wafer 700 forming a continuous and uniform ground throughout both the cap wafer 700 and the device wafer 720.

In some implementations, the areas of the first portion of the electrodes 702A, 702B on the cap wafer 700 and the electrodes 722A, 722B on the device wafer 720, and the height of the bonding bumps 732 can be designed and optimized to maximize capacitance and thus the capacitive coupling. In some implementations, the third portion of the coupling electrodes 702A, 702B on the recessed surface 710 and the depth of the recesses 712 can be also designed and optimized to minimize crosstalk and coupling. This methods and techniques presented here can reduce or eliminate needs for the capability to pattern across sidewalls of recesses.

In some implementations, the recess 712 on the cap wafer 700 include trenches, each of which is defined by a recessed trench surface and trench sidewalls. The recessed trench surface resides at a depth relative to the first surface 708 in the cap wafer 700. As shown in FIG. 7C, when the cap wafer 700 and the device wafer 720 are bonded, the trenches form enclosures that house the coplanar waveguide on the device wafer 720.

FIG. 8 is a flow chart showing aspects of an example fabrication process 800. In some implementations, the example process 800 may be used for fabricating a cap wafer with various superconducting circuitry at various positions, for example, the circuitry portion 214, 216, 218, 220, 222, 224 and another component in the cap wafer 212. The example process 800 may include additional or different operations, including operations to fabricate additional or different components, and the operations may be performed in the order shown or in another order. In some cases, operations in the example process 800 can be combined, iterated, or otherwise repeated or performed in another manner.

At 802, a substrate 822 is prepared. In some implementations, the substrate 822 is a float-zone, undoped, single-crystal silicon wafer with a high-resistivity. In some examples, the substrate 822 has a thickness of 320 μm, 670 μm, or another thickness. In some instances, a top surface 830 of the substrate 822 may be cleaned to remove the native oxide. For example, the substrate 822 can be cleaned using a HF etching process and rinsed with deionized (DI) water. In some instances, cleaning of the top surface 830 of the substrate 822 is performed to remove contaminants including organic contaminants and another type of contaminants. In some instances, the substrate 822 may be implemented as the second substrate 213 in FIG. 2 or in another manner.

At 804, a first photoresist layer 824 is patterned. In some implementations, the first photoresist layer 824 may include a negative or positive tone photoresist layer that is patternable in response to a photolithography light source. In some instances, the first photoresist layer 824 may include an e-beam (electron beam) resist layer (e.g., poly methyl methacrylate, methyl methacrylate, or another e-beam resist material) that is patternable in response to an e-beam lithography energy source. In some examples, before patterning, the first photoresist layer 824 is formed directly on the top surface 830 of the substrate 822 using a deposition process such as spin-coating, spray-coating, dip-coating, roller-coating, or another deposition method. After deposition, the first photoresist layer 824 is then patterned using a lithography process that may involve various exposure, developing, baking, stripping, etching, and rinsing processes. As a result, the first photoresist layer 824 is patterned such that openings 826 in the first photoresist layer 824 expose at least a portion of the top surface 830 of the substrate 822. In some implementations, positions of the openings 826 are determined according to the positions and arrangement of quantum circuit devices in one or more device wafers (e.g., the quantum circuit devices 204 in the device wafer 202 shown in FIG. 2) such that the recesses form respective enclosures that house the quantum circuit devices in the device wafer. In some examples, the first photoresist layer 824 has a thickness of 7 μm, or another thickness.

At 806, recesses 828 are formed in the substrate 822. In some implementations, the recesses 828 are formed by performing an etching process in the substrate 822 at the openings 826 using the first photoresist layer 824 as a mask. In some instances, recessed surfaces 831 are created at the bottom of the recesses 828 in the body of the substrate 822. Each of the recessed surfaces 831 resides at a depth of a few micrometers to a few tens of micrometers relative to the top surface 830 of the substrate 822. In some instances, the recesses 828 have a uniform depth of 24±1.5 μm or another depth. The recesses 828 are further defined by sidewalls 832, which can be perpendicular to the recessed surfaces 831 or slopped with respect to the recessed surface 831. In some cases, the recesses 828 may be implemented as the recesses 232 shown in FIG. 2, the recesses 406 in FIGS. 4A-4B, and the recesses 616, 650A, 650B, 650C, 650D as shown in FIGS. 6A-6B. In some instances, the recesses 828 may be formed using a dry etching method, for example, a Deep Reactive Ion Etching (DRIE) process, a cryogenic etching process, a gas-phase etching process, or another type of etching process.

After the formation of the recesses 828, the first patterned photoresist layer 824 may be removed. In some instances, the first photoresist layer 824 may be removed by one or more chemical cleaning processes using acetone, 1-Methyl-2-pyrrolidon (NMP), Dimethyl sulfoxide (DMSO), or other suitable removing chemicals. In some examples, the chemicals used may need to be heated to temperatures higher than room temperature to effectively dissolve the first photoresist layer 824. The selection of the remover is determined by the type and chemical structure of the first photoresist layer 824, and the substrate 822 to assure the chemical compatibility of the substrate 822 with the chemical cleaning process. In some implementations, this chemical cleaning process is then followed by a rinsing process using isopropyl alcohol or another chemical, and then using DI water.

At 808, a conductive layer 834 is deposited. In some implementations, the conductive layer 834 may include superconducting metals, superconducting metal alloys, or superconducting compound materials. In some instances, the conductive layer 834 may include multilayer superconductor-insulator heterostructures, stacks of superconducting layers, or another structure. In some examples, an interfacial silicide layer is formed between the conductive layer 834 and the substrate 822 during the deposition of the conductive layer 834 due to an interfacial reaction.

In some implementations, the conductive layer 834 may be deposited on the top surface 830, the recessed surfaces 831, and the sidewalls 832. For example, the conductive layer 834 includes a stack of conductive materials, e.g., Nb/TiW/Nb/MoRe having a total thickness of about 560 nanometers (nm). In some instances, the first conductive layer 834 may be deposited using a Chemical Vapor Deposition (CVD), Physical Vapor Deposition (PVD), or another deposition method.

At 810, a second photoresist layer 836 is patterned. In some instances, the second photoresist layer 836 is patterned on the top surface 830 and the recessed surfaces 831 of the substrate 822. In certain instances, a first portion of the second photoresist layer 836 with openings 838 may be formed on the top surface 830 of the substrate 822 under a first exposure setting and a second portion of the second photoresist layer 836 with openings 840 is formed on the recessed surfaces 831 of the substrate 822 under a second, distinct exposure setting (e.g., a different exposure time, different intensity of the light source, or a different wavelength of the light source). In some instances, the second photoresist layer 836 is deposited and patterned with respect to the operation 804 described above. In certain implementations, the second photoresist layer 836 has a thickness of about 14 μm or another thickness.

At 812, circuitry portions 842A, 842B are formed. In some implementations, a first circuitry portion 842A is formed on the top surface 830 of the substrate 822 corresponding to the openings 838 in the first portion of the second photoresist layer 836. A second circuitry portion 842B is formed on the recessed surfaces 831 of the substrate 822 corresponding to the openings 840 in the second portion of the second photoresist layer 836. In some implementations, the circuitry 842A, 842B are formed by performing an etching process to remove the conductive layer 834 exposed at the openings 838, 840 without over-etching the substrate 822. In some instances, the first circuitry portion 842A may be implemented as the circuitry portion 214 in FIG. 2, the ground plane 426 in FIGS. 4A-4B, the circuitry portion 621A, 621B in FIG. 6A, 660 in FIG. 6B, or the coplanar waveguide 680B/682B in FIG. 6C. In some instances, the second circuitry portion 842B may be implemented as the circuitry portion 216 in FIG. 2, the control line 416 or the planar loop 430 of the control line 416 in FIGS. 4A-4B, the planar resonators 504A-504G in FIG. 5, the circuitry portion 626 on the recessed surface 618 in FIG. 6A, and the circuitry portion 656A/656B in FIG. 6B.

At 814, a third photoresist layer 844 is patterned. As shown in FIG. 8, the third photoresist layer 844 after patterning includes openings 846 at the top surface 830 of the substrate 822. In some examples, the third photoresist layer 844 may have a thickness of 18 μm or another thickness. In some implementations, the third photoresist layer 844 is deposited and patterned with respect to the operation 804 described above.

At 816, bonding bumps 848 are formed. As shown in FIG. 8, the bonding pumps 848 are formed on the top surface 830 of the substrate 822 corresponding to the openings 846 in the third photoresist layer 844. In some instances, the bonding bumps 848 are formed by depositing a metallization layer on the substrate 822 with the patterned third photoresist layer 844. In some instances, the metallization layer may include indium (In) and another conductive material. In some instances, the metallization layer may have a thickness in a range of 6-7 micrometers (μm). In some implementations, the metallization layer can be deposited using PVD, CVD, electrodeposition, or another method. After depositing the metallization layer, the third photoresist layer 844 can be removed with respect to the operation 806. In some implementations, the height of the bonding bumps 848 after bonding the cap wafer with a device wafer can be less than the thickness of the metallization layer from deposition. For example, a bonding process with a bonding force of a few tens of newton (N) per square millimeter (mm²) can cause a compression to the bonding bumps which defines the gap separating the two respective surfaces of the device wafer and the cap wafer. In some instances, a bonding force is selected to cause a compression of more than 40% the total height of the bonding bumps, resulting the gap in a range of ≤3 μm, or in another range.

In a general aspect, a quantum processing unit (QPU) includes a cap wafer that includes multiple circuitry portions that are connected to each other. The cap wafer may provide advanced or improved functionality during operation of the QPU.

In a first example, a quantum processing unit includes a first substrate (e.g., the cap wafers 212, 304, 324, 404, 500, 604, 634, 674, or 720 shown in FIG. 2, 3A-3B, 4A-4B, 5, 6A-6C, or 7A-7C) and a second substrate (e.g., the device wafers 202, 302A, 302B, 302C, 322A, 322B, 322C, 322D, 402, 602, 632, 672, or 720, shown in FIG. 2, 3A-3B, 4A-4B, 6A-6C, or 7A-7C). The first substrate includes a first surface, a recess, and first superconducting circuitry. The recess is defined by one or more sidewalls and a recessed surface. The recessed surface resides at a depth in the first substrate relative to the first surface. The first superconducting circuitry includes a first circuitry portion (e.g., the circuitry portions 214, 621A, 621B, 658, the central conductive line 680B and the ground planes 682B, electrodes 702A, 702B, the ground plane 704, or the circuitry portion 842A shown in FIG. 2, 6A-6C, 7A-7C, or 8) on the first surface of the first substrate; a second circuitry portion (e.g., the circuitry portion 216, the planar loop 430, the control line 416, the planar resonators 504A-504G, the circuitry portion 626 on the recessed surface 618, the circuitry portions 656A, 656B, the connection 716, or the circuitry portion 842B shown in FIG. 2, 4A-4B, 5, 6A-6B, 7A-7C, or 8) on the recessed surface of the first substrate; and a connection (e.g., the conductive lines 218, the ground planes 426 on the sidewalls of the recess 406, the circuitry portion 626 on the sidewalls 620, the conductive lines 648, the electrodes 702A, 702B on the sidewalls 709 shown in FIG. 2, 4A-4B, 6A-6B, or 7A-7C) disposed on at least one of the one or more sidewalls and connecting the first circuitry portion and the second circuitry portion. The second substrate includes second superconducting circuitry. The second superconducting circuitry includes a quantum circuit device (e.g., the quantum circuit device 204 shown in FIG. 2, the qubit devices 306, the tunable coupler devices 308 shown in FIG. 3A, the quantum circuit device 408 shown in FIGS. 4A-4B, or the quantum circuit devices 642A, 642B, 642C and 642D shown in FIG. 6B). The first and second substrates are arranged such that the recess forms an enclosure that houses the quantum circuit device.

Implementations of the first example may include one or more of the following features. The connection includes a conductive connection. The connection includes a capacitive connection. The connection includes an inductive connection. The connection includes a metal coating that covers the one or more sidewalls. The connection includes a patterned metal coating that covers a portion of the one or more sidewalls.

Implementations of the first example may include one or more of the following features. The first superconducting circuitry includes a control line configured to communicate control signals to or from the quantum circuit device. The control line includes a microwave line (e.g., the circuitry portion 214 shown in FIG. 2) that is capacitively coupled to the quantum circuit device. The control line includes a flux bias line that is inductively coupled to the quantum circuit device. The quantum circuit device includes a superconducting quantum interface device (SQUID) loop (e.g., the SQUID 409 shown in FIGS. 4A-4B), and the flux bias line is inductively coupled to the SQUID loop. The second circuitry portion includes a readout resonator (e.g., the circuitry portion 216 shown in FIG. 2) connected to the control line and configured to interact with the quantum circuit device. The second circuitry portion includes a tunable coupler device (e.g., the circuitry portion 216 in FIG. 2) connected to the control line and configured to interact with the quantum circuit device. The first superconducting circuitry includes a conductive connection disposed in a via (e.g., the conductive vias 222A, 222B in FIG. 2) defined in the first substrate.

Implementations of the first example may include one or more of the following features. The first substrate includes a second surface opposite the first surface, a first set of vias (e.g., the conductive vias 222A in FIG. 2, or the conductive vias 622-1A, 622-2A in FIG. 6A), and a second set of vias (e.g., the conductive vias 222B in FIG. 2, the conductive via 622B in FIG. 6A, or the conductive vias 652A, 652B in FIG. 6B). The first set of vias extends through the first substrate from the second surface to the first surface. The second set of vias extends through the first substrate from the second surface to the recessed surface. The first superconducting circuitry includes a first set of conductive connections and a second set of conductive connections. The first set of conductive connections is disposed in the first set of vias and connected to the first circuitry portion. The second set of conductive connections is disposed in the second set of vias and connected to the second circuitry portion. The first superconducting circuitry includes a third circuitry portion (e.g., the circuitry portion 220 in FIG. 2, the circuitry portions 624A, 624B, and 628 in FIG. 6A, or the circuitry portion 660 in FIG. 6B) on the second surface of the first substrate. The first set of conductive connections connects the first circuitry portion and the third circuitry portion. The second set of conductive connections connects the second circuitry portion and the third circuitry portion. The second circuitry portion is connected to ground through at least one of the second set of conductive connections.

Implementations of the first example may include one or more of the following features. The second circuitry portion includes one or more circuit elements that are capacitively coupled with the quantum circuit device. The first circuitry portion comprises one or more circuit elements that are capacitively coupled to the second superconducting circuitry. The first circuitry portion comprises one or more circuit elements that are galvanically coupled to the second superconducting circuitry. The first and second substrates are separated by a gap that is under vacuum during operation of the quantum processing unit. The gap is defined by bonding bumps (e.g., the bonding bumps 224, 428, 606A, 606B, 654, 684, 732, or 848 in FIG. 2, 4A-4B, 6A-6C, 7C, or 8) between the first and second substrates, and the bonding bumps include a conductive material. The gap is less than or equal to three micrometers (3 μm). The one or more sidewalls are one or more cavity sidewalls, and the recessed surface is a recessed cavity surface. The first substrate further includes a trench (e.g., the recess 712 in FIGS. 7A-7C) defined by one or more trench sidewalls and a recessed trench surface. The recessed trench surface resides at a depth in the first substrate relative to the first surface. The second superconducting circuitry further includes a coplanar waveguide (e.g., the coplanar waveguides 680A/682A, 680B/682B, or 728/724A/724B in FIG. 6A-6C, or 7A-7C). The first and second substrates are arranged such that the trench forms an enclosure that houses the coplanar waveguide. The one or more sidewalls are perpendicular to the first surface and the recessed surface.

In a second example, quantum information is processed by operation of a quantum processing unit. The quantum processing unit includes a first substrate and a second substrate. The first substrate includes a first surface, a recess, and first superconducting circuitry. The recess is defined by one or more sidewalls and a recessed surface. The recessed surface resides at a depth in the first substrate relative to the first surface. The first superconducting circuitry includes a first circuitry portion on the first surface of the first substrate; a second circuitry portion on the recessed surface of the first substrate; and a connection disposed on at least one of the one or more sidewalls and connecting the first circuitry portion and the second circuitry portion. The second substrate includes second superconducting circuitry. The second superconducting circuitry includes a quantum circuit device. The first and second substrates are arranged such that the recess forms an enclosure that houses the quantum circuit device. When the quantum information is processed, signals to or from the quantum circuit device are communicated through control lines defined by at least one of the first superconducting circuitry or the second superconducting circuitry.

Implementations of the second example may include one or more of the following features. The connection includes a conductive connection. The connection includes a capacitive connection. The connection includes an inductive connection. The connection includes a metal coating that covers the one or more sidewalls. The connection includes a patterned metal coating that covers a portion of the one or more sidewalls.

Implementations of the second example may include one or more of the following features. The control lines include a microwave line that is capacitively coupled to the quantum circuit device. When signals are communicated to or from the quantum circuit device, microwave signals are communicated on the microwave line. The control lines include a flux bias line that is inductively coupled to the quantum circuit device. When signals are communicated to or from the quantum circuit device, flux bias signals are communicated on the flux bias line. The quantum circuit device includes a superconducting quantum interface device (SQUID) loop, and the flux bias line is inductively coupled to the SQUID loop. The flux bias signals control a magnetic flux applied to the SQUID loop. The second circuitry portion includes a readout resonator connected to the control lines and configured to interact with the quantum circuit device. When the quantum information is processed, the readout resonator is operated. The second circuitry portion includes a tunable coupler device connected to the control lines and configured to interact with the quantum circuit device. When the quantum information is processed, the tunable coupler device is operated. The first superconducting circuitry includes a conductive connection disposed in a via defined in the first substrate. When signals are communicated to or from the quantum circuit device, signals are communicated on the conductive connection disposed in the via.

Implementations of the second example may include one or more of the following features. The first substrate includes a second surface opposite the first surface, a first set of vias, and a second set of vias. The first set of vias extends through the first substrate from the second surface to the first surface. The second set of vias extends through the first substrate from the second surface to the recessed surface. The first superconducting circuitry includes a first set of conductive connections and a second set of conductive connections. The first set of conductive connections is disposed in the first set of vias and connected to the first circuitry portion. The second set of conductive connections is disposed in the second set of vias and connected to the second circuitry portion. The first superconducting circuitry includes a third circuitry portion on the second surface of the first substrate. The first set of conductive connections connects the first circuitry portion and the third circuitry portion. The second set of conductive connections connects the second circuitry portion and the third circuitry portion. When the signals are communicated to or from the quantum circuit device, the signals are communicated on at least one of the conductive connections of the first and second set of conductive connections. The second circuitry portion is connected to ground through at least one of the second set of conductive connections.

Implementations of the second example may include one or more of the following features. The second circuitry portion includes one or more circuit elements that are capacitively coupled with the quantum circuit device. The first circuitry portion comprises one or more circuit elements that are capacitively coupled to the second superconducting circuitry. The first circuitry portion comprises one or more circuit elements that are galvanically coupled to the second superconducting circuitry. The first and second substrates are separated by a gap. The gap is held under a vacuum pressure during operation of the quantum processing unit. The gap is defined by bonding bumps between the first and second substrates, and the bonding bumps include a conductive material. The gap is less than or equal to three micrometers (3 μm). The one or more sidewalls are one or more cavity sidewalls, and the recessed surface is a recessed cavity surface. The first substrate further includes a trench defined by one or more trench sidewalls and a recessed trench surface. The recessed trench surface resides at a depth in the first substrate relative to the first surface. The second superconducting circuitry further includes a coplanar waveguide. The first and second substrates are arranged such that the trench forms an enclosure that houses the coplanar waveguide. When signals are communicated to or from the quantum circuit device, the signals are communicated on the coplanar waveguide. The one or more sidewalls are perpendicular to the first surface and the recessed surface.

In a third example, a quantum processing unit includes a cap wafer and a device wafer. The cap wafer includes a first surface, a plurality of recesses, and a first superconducting circuitry. Each recess is defined by one or more sidewalls and a recessed surface. The recessed surface resides at a depth in the first substrate relative to the first surface. The first superconducting circuitry includes a first circuitry portion, second circuitry portions, and connections. The first circuitry portion resides on the first surface of the first substrate. The second circuitry portions reside on the recessed surfaces of the respective recesses. The connections disposed on at least one of the one or more sidewalls of the respective recesses. Each connection connects the first circuitry portion and a respective one of the second circuitry portions. The device wafer includes second superconducting circuitry. The second superconducting circuitry includes a plurality of quantum circuit devices. The cap wafer and the device wafer are arranged such that the recesses form respective enclosures that house the quantum circuit devices.

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple implementations separately or in any suitable subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

A number of embodiments have been described. Nevertheless, it will be understood that various modifications can be made. Accordingly, other embodiments are within the scope of the following claims.

1. A quantum processing unit comprising:
a first substrate comprising:
a first surface;
a recess defined by one or more sidewalls and a recessed surface, the recessed surface residing at a depth in the first substrate relative to the first surface,
first superconducting circuitry comprising:
a first circuitry portion on the first surface of the first substrate;
a second circuitry portion on the recessed surface of the first substrate; and
a connection disposed on at least one of the one or more sidewalls and connecting the first circuitry portion and the second circuitry portion; and
a second substrate comprising second superconducting circuitry, the second superconducting circuitry comprising a quantum circuit device, the first and second substrates being arranged such that the recess forms an enclosure that houses the quantum circuit device.

2. The quantum processing unit of claim 1, wherein the connection comprises a conductive connection.

3. The quantum processing unit of claim 1, wherein the connection comprises a capacitive connection.

4. The quantum processing unit of claim 1, wherein the connection comprises an inductive connection.

5. The quantum processing unit of claim 1, wherein the connection comprises a metal coating that covers the one or more sidewalls.

6. The quantum processing unit of claim 1, wherein the connection comprises a patterned metal coating that covers a portion of the one or more sidewalls.

7. The quantum processing unit of claim 1, wherein the first superconducting circuitry comprises a control line configured to communicate control signals to or from the quantum circuit device.

8. The quantum processing unit of claim 7, wherein the control line comprises a microwave line that is capacitively coupled to the quantum circuit device.

9. The quantum processing unit of claim 7, wherein the control line comprises a flux bias line that is inductively coupled to the quantum circuit device.

10. (canceled)

11. The quantum processing unit of claim 7, wherein the second circuitry portion comprises a readout resonator connected to the control line and configured to interact with the quantum circuit device.

12. The quantum processing unit of claim 7, wherein the second circuitry portion comprises a tunable coupler device connected to the control line and configured to interact with the quantum circuit device.

13. The quantum processing unit of claim 7, wherein the control line comprises the connection disposed on at least one of the one or more sidewalls.

14-17. (canceled)

18. The quantum processing unit of claim 1, wherein the second circuitry portion comprises one or more circuit elements that are capacitively coupled with the quantum circuit device.

19. The quantum processing unit of claim 1, wherein the second circuitry portion comprises one or more circuit elements that are inductively coupled with the quantum circuit device.

20. The quantum processing unit of claim 1, wherein the first circuitry portion comprises one or more circuit elements that are capacitively coupled to the second superconducting circuitry.

21. The quantum processing unit of claim 1, wherein the first circuitry portion comprises one or more circuit elements that are galvanically coupled to the second superconducting circuitry.

22-26. (canceled)

27. A quantum information processing method comprising:
processing quantum information by operation of a quantum processing unit, wherein the quantum processing unit comprises:
a first substrate comprising:
a first surface;
a recess defined by one or more sidewalls and a recessed surface, the recessed surface residing at a depth in the first substrate relative to the first surface,
first superconducting circuitry comprising:
a first circuitry portion on the first surface of the first substrate;
a second circuitry portion on the recessed surface of the first substrate; and
a connection disposed on at least one of the one or more sidewalls and connecting the first circuitry portion and the second circuitry portion; and
a second substrate comprising second superconducting circuitry, the second superconducting circuitry comprising a quantum circuit device, the first and second substrates being arranged such that the recess forms an enclosure that houses the quantum circuit device,
wherein processing the quantum information comprises communicating signals to or from the quantum circuit device through control lines defined by at least one of the first superconducting circuitry or the second superconducting circuitry.

28. The method of claim 27, wherein the connection comprises a conductive connection.

29. The method of claim 27, wherein the connection comprises a capacitive connection.

30. The method of claim 27, wherein the connection comprises an inductive connection.

31-50. (canceled)
